(19) United States
(12) Patent Application Publication
(10) Pub. No.: US 2013/0238262 A1
(43) Pub. Date: Sep. 12, 2013

(54) MEASUREMENT APPARATUS, MEASUREMENT METHOD, AND PROGRAM

(71) Applicant: ADVANTEST CORPORATION, Tokyo (JP)

(72) Inventor: Koji ASAMI, Saitama (JP)

(73) Assignee: ADVANTEST CORPORATION, Tokyo (JP)

(21) Appl. No.: 13/747,485

(22) Filed: Jan. 23, 2013

(30) Foreign Application Priority Data
Mar. 9, 2012 (JP) 2012-052974

(51) Int. Cl. G01R 31/317

(52) U.S. Cl. CPC G01R 31/31706
USPC 702/58

(57) ABSTRACT

A measurement apparatus comprising an IQ error measuring section that measures a frequency characteristic of an IQ error of a device under measurement; and an error amount calculating section that calculates EVM based on a constellation error, at each of a plurality of frequencies, between an ideal signal to be output in response to input of a predetermined signal into a model of the device under measurement that does not include an IQ error and a prediction signal that is to be output in response to the input of the predetermined signal into a model of the device under measurement that includes the IQ error measured by the IQ error measuring section, wherein the error amount calculating section corrects a signal component at each of the frequencies in the prediction signal according to a channel characteristic, and calculates the constellation error.

### BACKGROUND

1. Technical Field

The present invention relates to a measurement apparatus, a measurement method, and a program.

2. Related Art

When evaluating a digital communication device, one item of the evaluation is referred to as EVM (Error Vector Magnitude). A manufacturer of a digital communication device measures the EVM of the digital communication devices when the devices are shipped, to determine pass/fail and makes adjustments to the devices, for example.

When shipping a plurality of digital communication devices that conform to a standard, the manufacturer must measure the EVM of each communication standard. Furthermore, depending on the communication standard, the signal supplied to the digital communication device can be long, which results in a long measurement time.

### SUMMARY

Therefore, it is an object of an aspect of the innovations herein to provide a measurement apparatus, a measurement method, and a program, which are capable of overcoming the above drawbacks accompanying the related art. The above and other objects can be achieved by combinations described in the claims. According to a first aspect of the present invention, provided is a measurement apparatus that measures a characteristic of a device under measurement, which includes a quadrature modulator or a quadrature demodulator, the measurement apparatus comprising an IQ error measuring section that measures a frequency characteristic of an IQ error of the device under measurement; and an error amount calculating section that calculates EVM based on a constellation error, at each of a plurality of frequencies, between an ideal signal to be output in response to input of a predetermined signal into a model of the device under measurement that does not include an IQ error and a prediction signal that is to be output in response to the input of the predetermined signal into a model of the device under measurement that includes the IQ error measured by the IQ error measuring section. The error amount calculating section corrects a signal component at each of the frequencies in the prediction signal according to a channel characteristic, and calculates the constellation error.

The summary clause does not necessarily describe all necessary features of the embodiments of the present invention. The present invention may also be a sub-combination of the features described above.

### BRIEF DESCRIPTION OF THE DRAWINGS

FIG. 1 shows a configuration of a measurement apparatus 10 according to an embodiment of the present invention, along with a device under measurement 200.

FIG. 2 shows a model of a quadrature modulator that includes an IQ error.

FIG. 3 shows a model of a quadrature demodulator that includes an IQ error.

FIG. 4 shows examples of an ideal signal to be output from the device under measurement 200, a measured signal that is actually output from the device under measurement 200, and an error vector indicating the constellation error between the ideal signal and the measured signal.

FIG. 5 shows a configuration of the error amount calculating section 30 that calculates the EVM of a device under measurement 200 that modulates or demodulates an OFDM signal.

FIG. 6 shows an angular frequency component ω₀ of the ideal signal calculated by the ideal signal calculating section 32.

FIG. 7 shows an angular frequency ω₀ component of a prediction signal calculated by the prediction signal calculating section 34. The prediction signal is affected by the IQ error of the device under measurement 200.

FIG. 8 shows a configuration of an error amount calculating section 30 that calculates the EVM of a device under measurement 200 that modulates or demodulates SC-FDMA signals.

FIG. 9 shows an exemplary filter characteristic (H_{I}(ω) of the I-signal path of the device under measurement 200.

FIG. 10 shows an exemplary filter characteristic (H_{Q}(ω) of the Q-signal path of the device under measurement 200.

FIG. 11 shows a configuration of a modification of the measurement apparatus 10 according to the present embodiment, along with the device under measurement 200.

FIG. 12 shows a configuration of the IQ error measuring section 20 according to the present embodiment, along with a quadrature modulator 300.

FIG. 13 shows an exemplary multi-tone signal output from an ideal quadrature modulator when the quadrature modulator is simultaneously supplied with a reference I signal and a reference Q signal.

FIG. 14 shows exemplary timings at which the reference I signal and the reference Q signal are supplied to the quadrature modulator 300.

FIG. 15 shows an error model of the quadrature modulator 300.

FIG. 16 shows exemplary frequency characteristics of the IQ error.

FIG. 17 shows an exemplary process flow of the calculating section 122 according to the present embodiment.

FIG. 18 shows an exemplary configuration of the IQ error measuring section 20 according to a modification of the present embodiment, along with a quadrature demodulator 400.

FIG. 19 shows an example of a hardware configuration of a computer 1900 according to the present embodiment.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

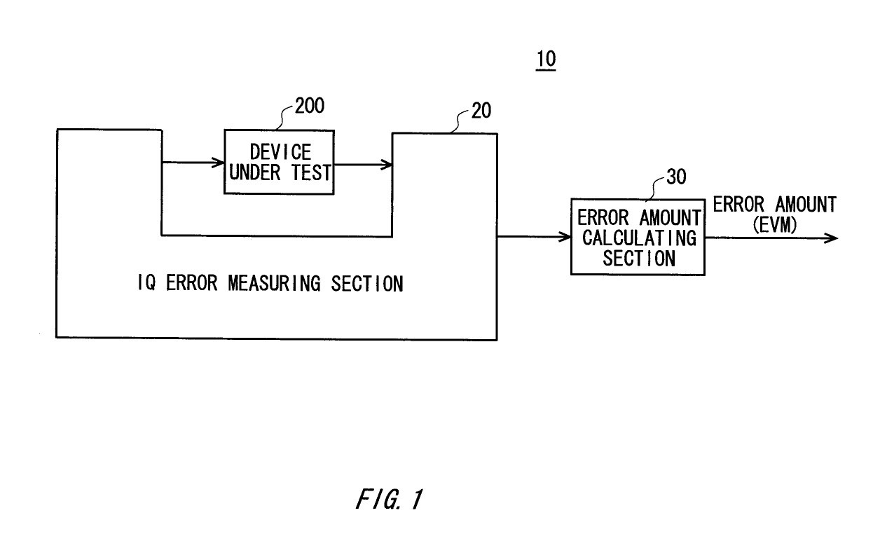

FIG. 1 shows a configuration of a measurement apparatus 10 according to an embodiment of the present invention, along with a device under measurement 200. The measurement apparatus 10 measures characteristics of the device under measurement 200, which includes a quadrature modulator and a quadrature demodulator. In the present embodiment, the measurement apparatus 10 measures the EVM (Error Vector Magnitude) of the device under measurement 200.

The measurement apparatus 10 includes an IQ error measuring section 20 and an error amount calculating section 30. The IQ error measuring section 20 measures the frequency characteristic of an IQ error of the device under measurement 200.

Here, the frequency characteristic of the IQ error of the device under measurement 200 can be expressed as shown below.

H(ω)=(H_{Q}(ω)/H_{I}(ω))·e^{jθ}

In this expression, H(ω) represents the frequency characteristic of the IQ error of the device under measurement 200, H_{I}(ω) represents the filter characteristic of the I-signal path of the device under measurement 200, H_{Q}(ω) represents the filter characteristic of the Q-signal path of the device under measurement 200, and θ represents the carrier phase error.

In other words, the frequency characteristic of the IQ error of the device under measurement 200 can be represented as a characteristic obtained by phase-shifting the ratio of the filter characteristic of the Q-signal path of the device under measurement 200 relative to the filter characteristic of the I-signal path of the device under measurement 200, by an amount corresponding to the carrier phase error.

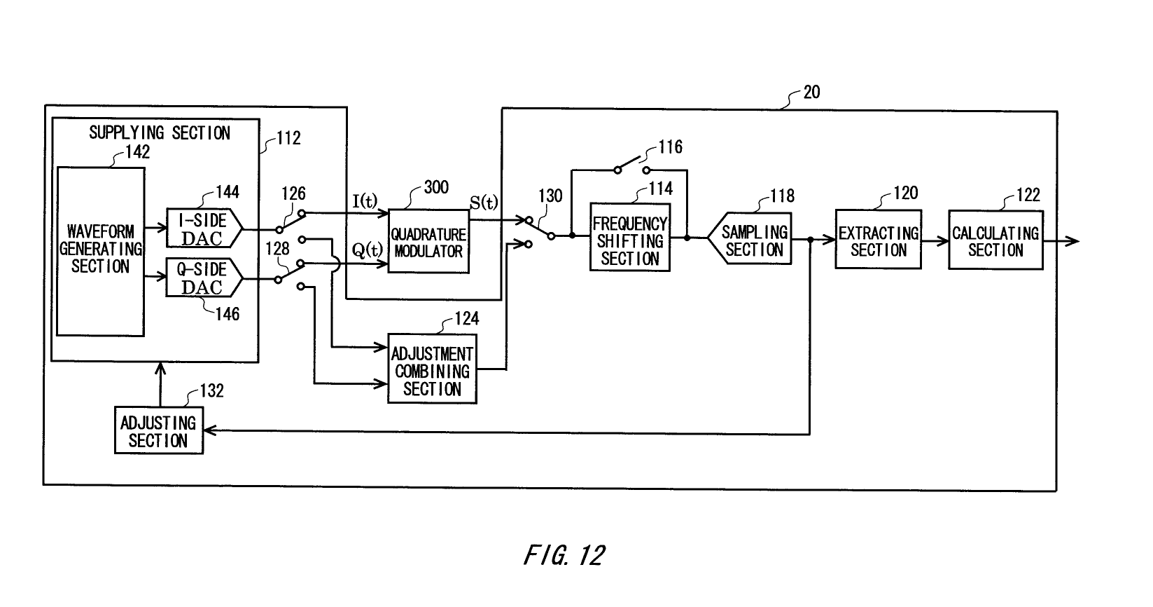

The IQ error measuring section 20 of the present embodiment measures the filter characteristic H_{I}(ω) of the I-signal path and the filter characteristic H_{Q}(ω) of the Q-signal path, when the frequency characteristic of the IQ error is divided into the filter characteristic of the I-signal path and the filter characteristic of the Q-signal path. Furthermore, the IQ error measuring section 20 measures the phase error (carrier phase error θ) between the carrier signal provided on the I-signal path of the device under measurement 200 and the carrier signal provided on the Q-signal path. The IQ error measuring section 20 is described in further detail in FIG. 12 and onward.

The error amount calculating section 30 calculates the error amount when a prescribed signal is supplied to the device under measurement 200, based in the frequency characteristic of the IQ error of the device under measurement 200 measured by the IQ error measuring section 20. In the present embodiment, the error amount calculating section 30 calculates EVM of the device under measurement 200.

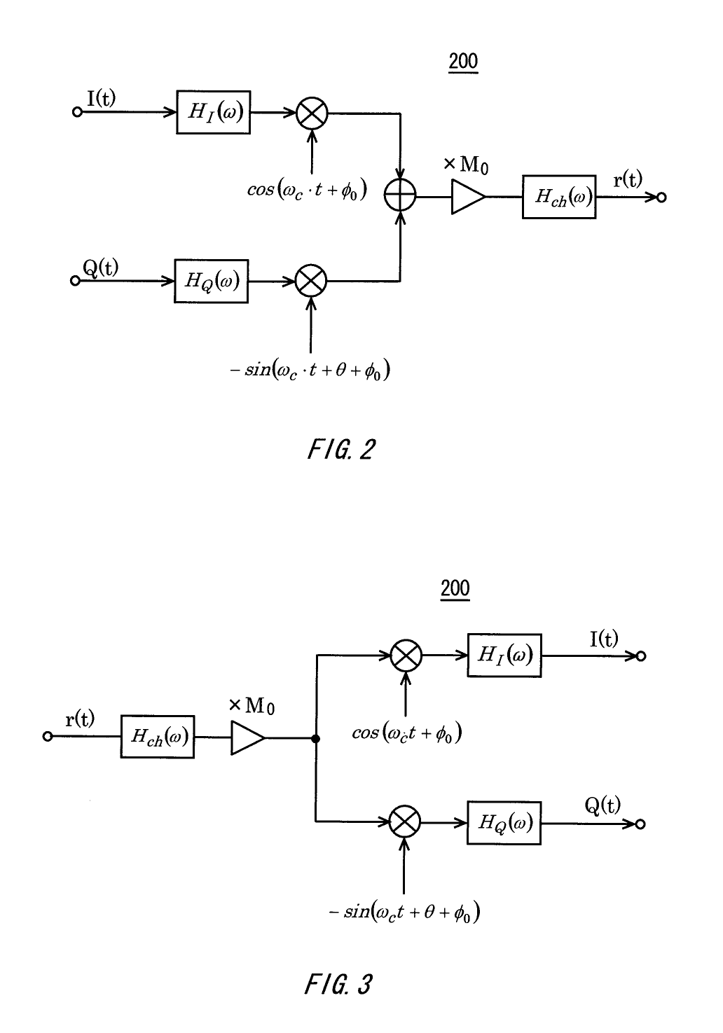

FIG. 2 shows a model of a quadrature modulator that includes an IQ error. FIG. 3 shows a model of a quadrature demodulator that includes an IQ error.

As shown in FIG. 2, the quadrature modulator including the IQ error is expressed as a model that includes the filter characteristic H_{I}(ω) of the I-signal path and the filter characteristic H_{Q}(ω) of the Q-signal path. In the model for the quadrature modulator including the IQ error, the filter characteristic H_{I}(ω) of the I-signal path is inserted between the input end of the I component (I(t)) of the baseband signal and the I-side multiplier. Furthermore, In the model for the quadrature modulator including the IQ error, the filter characteristic H_{Q}(ω) of the Q-signal path is inserted between the input end of the Q component (Q(t)) of the baseband signal and the Q-side multiplier.

A quadrature modulator including a channel characteristic is represented by a model that further includes a channel characteristic H_{ch}(ω). In the model of the quadrature modulator including the channel characteristic, the channel characteristic H_{ch}(ω) is inserted between an amplifier that amplifies a modulated signal (r(t)) and an output end of the modulated signal (r(t)).

As shown in FIG. 3, the quadrature demodulator including the IQ error is represented by a model that includes the filter characteristic H_{I}(ω) of the I-signal path and the filter characteristic H_{Q}(ω) of the Q-signal path. In the model of the quadrature demodulator including the IQ error, the filter characteristic H_{I}(ω) of the I-signal path is inserted between the I-side multiplier and the output end of the I component (I(t)) of the baseband signal. Furthermore, in the model of the quadrature demodulator including the IQ error, the filter characteristic H_{Q}(ω) of the Q-signal path is inserted between the Q-side multiplier and the output end of the Q component (Q(t)) of the baseband signal.

A quadrature demodulator including a channel characteristic is represented by a model that includes a channel characteristic H_{ch}(ω). In the model of the quadrature demodulator including the channel characteristic, the channel characteristic H_{ch}(ω) is inserted between an input end of the modulated signal (r(t)) and an amplifier that amplifies the modulated signal (r(t)).

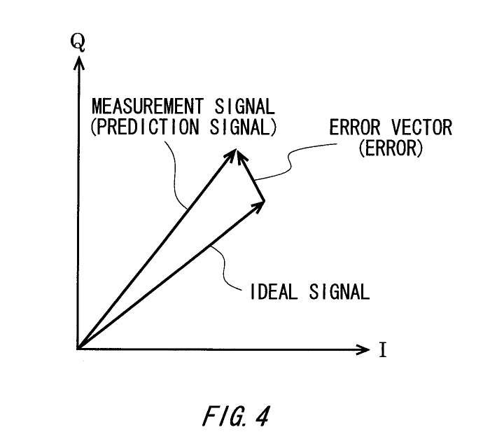

FIG. 4 shows examples of an ideal signal to be output from the device under measurement 200, a measured signal that is actually output from the device under measurement 200, and an error vector indicating the constellation error between the ideal signal and the measured signal. A baseband signal of predetermined signal points is modulated by the quadrature modulator, and the resulting modulated signal is demodulated by an ideal quadrature demodulator. In this case, the demodulated baseband signal includes an error relative to the ideal signal, i.e. the baseband signal input to the quadrature modulator. This error is caused by the quadrature modulator, and is expressed as a constellation error, which is the error vector when the modulated signal (the signal after modulation) is plotted in the IQ coordinate plane.

Furthermore, it is assumed that a baseband signal of predetermined signal points is modulated by an ideal quadrature modulator, and the resulting modulated signal is demodulated by the quadrature demodulator. In this case, the demodulated baseband signal includes an error relative to the ideal signal, i.e. the baseband signal input to the ideal quadrature modulator. This error is caused by the quadrature demodulator, and is expressed as a constellation error, which is the error vector when the modulated signal (the signal before demodulation) is plotted in the IQ coordinate plane.

The EVM of the quadrature modulator and the quadrature demodulator is the root mean square (RMS) of the error vector with respect to the signal points. The EVM indicates the quality of the quadrature modulator and the quadrature demodulator. For example, an EVM measurement apparatus usually provides a device under measurement with a baseband signal indicating a plurality of predetermined signal points, e.g. a baseband signal defined by a communication standard, and measures the signal points of the signal output from the device under measurement. The EVM measurement apparatus calculates the root mean square of the error vector of the measured signal points, and outputs the result of this calculation as the EVM.

Here, in the error amount calculating section 30 according to the present embodiment, the value corresponding to the EVM is calculated based on the frequency characteristic of the IQ error measured by the IQ error measuring section 20. More specifically, the error amount calculating section 30 calculates the ideal signal to be output in response to the input of a predetermined signal, e.g. a signal defined by a communication standard, into the model of the device under measurement 200 that does not include an IQ error. Furthermore, the error amount calculating section 30 calculates a prediction signal that is to be output in response to the input of a predetermined signal, e.g. a signal defined by a communication standard, into the model of the device under measurement 200 that includes the IQ error measured by the IQ error measuring section 20. The error amount calculating section 30 calculates the EVM based on the error between the ideal signal and the prediction signal.

The measurement apparatus 10 including the error amount calculating section 30 can calculate the EVM without measuring the output signal occurring when the predetermined signal, e.g. a signal defined by a communication standard, is actually input to the device under measurement 200. Therefore, the measurement apparatus 10 can measure the EVM easily and in a short time.

The error amount calculating section 30 may calculate the EVM by using, as the predetermined signal, a signal of the signal points with the greatest signal strength. Specifically, the error amount calculating section 30 may calculate the EVM based on the error between the ideal signal and the prediction signal that are to be output when the signal of the signal points having the greatest signal strength is input to the model of the device under measurement 200. In this way, the error amount calculating section 30 can measure the worst EVM value of the device under measurement 200.

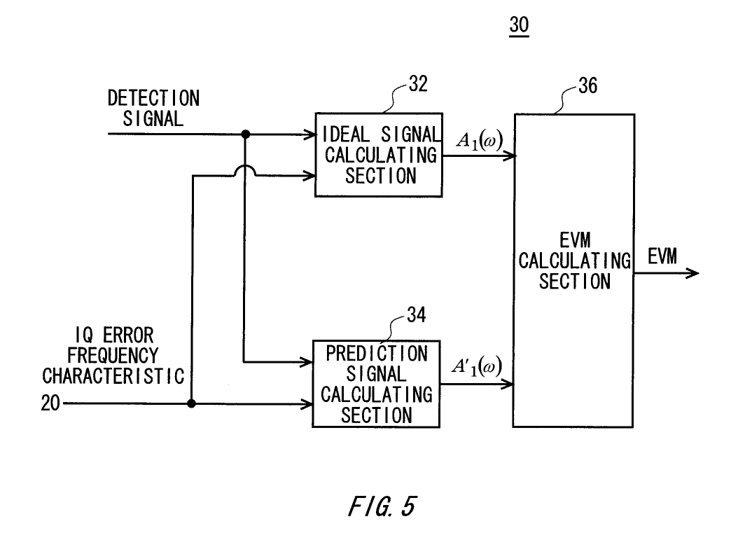

FIG. 5 shows a configuration of the error amount calculating section 30 that calculates the EVM of a device under measurement 200 that modulates or demodulates an OFDM (Orthogonal Frequency Division Multiplexing) signal. When the EVM of a device under measurement 200 that modulates or demodulates an OFDM signal is to be calculated, the error amount calculating section 30 includes an ideal signal calculating section 32, a prediction signal calculating section 34, and an EVM calculating section 36.

The ideal signal calculating section 32 calculates the ideal signal to be output in response to the input of a predetermined signal into the model of the device under measurement 200 that does not include an IQ error. For example, the ideal signal calculating section 32 may calculate the ideal signal to be output in response to the input, into the ideal model of the device under measurement 200 that does not include an IQ error, of a detection signal for calculating the EVM defined by a communication standard, e.g. IEEE 802.11a, used for the OFDM signal.

The prediction signal calculating section 34 calculates the prediction signal that is predicted to be output in response to the input of the predetermined signal into the model of the device under measurement 200 that includes the IQ error measured by the IQ error measuring section 20. For example, the prediction signal calculating section 34 may calculate the prediction signal to be output in response to the input, into the model of the device under measurement 200 that includes the IQ error measured by the IQ error measuring section 20, a signal that is the same as the detection signal input to the ideal signal calculating section 32.

For each symbol of the OFDM signal, the EVM calculating section 36 calculates the constellation error (distance) between the ideal signal and the prediction signal at each of a plurality of frequencies, i.e. the sub-carriers. Furthermore, for each symbol, the EVM calculating section 36 calculates the root mean square of the constellation error (distance) at each of the plurality of frequencies, i.e. the sub-carriers. The EVM calculating section 36 outputs, as the EVM, the root mean square calculated for each symbol. Instead, the EVM calculating section 36 may output, as the EVM, the average of the root mean square calculated for a plurality of symbols of the OFDM signal.

In this way, the error amount calculating section 30 can calculate the EVM without needing to measure the output signal that is actually output in response to the detection signal, which conforms to an OFDM standard, being input to the device under measurement 200. Therefore, the measurement apparatus 10 can calculate the EVM of the device under measurement 200, which modulates or demodulates an OFDM signal, in a short time using a simple process.

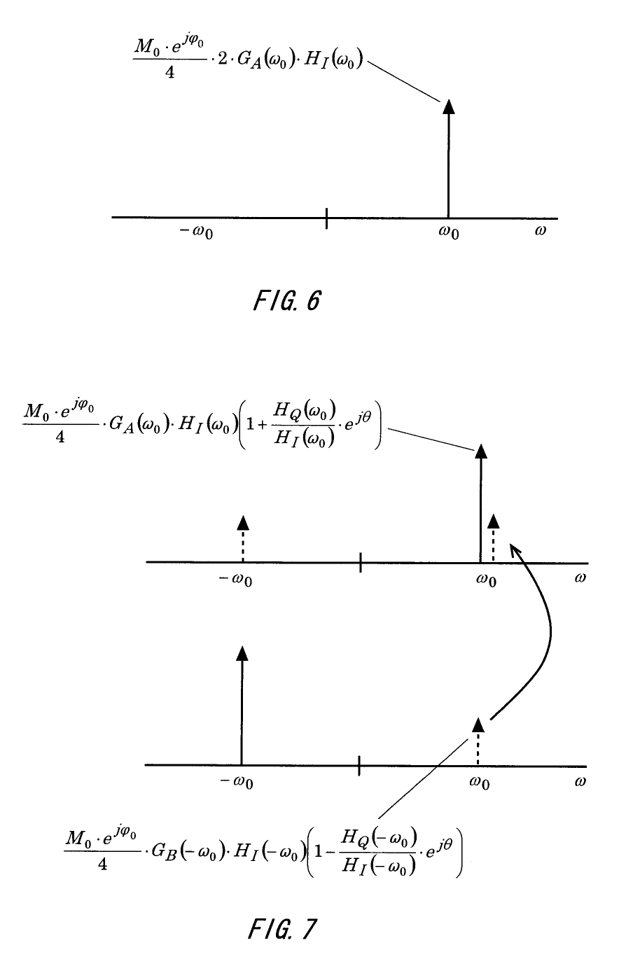

FIG. 6 shows an angular frequency component ω₀ of the ideal signal calculated by the ideal signal calculating section 32. The ideal signal is not affected by the IQ error of the device under measurement 200. Accordingly, the component A(ω₀) of a given angular frequency ω₀ in the ideal signal neither affects the DC-symmetric mirror angular frequency (−ω₀) nor is affected by the mirror angular frequency (−ω₀). Accordingly, the component A(ω₀) of a given angular frequency ω₀ in the ideal signal can be expressed as shown below in Expression 111.

$${A}_{1} ( {ω}_{0} ) = \frac{{M}_{0} \cdot {e}^{j {ϕ}_{0}}}{4} \cdot 2 \cdot {G}_{A} ( {ω}_{0} ) \cdot {H}_{I} ( {ω}_{0} ) \qquad ( 111 )$$

Here, ω₀ represents the angular frequency, M₀ represents the gain of the modulated signal in the model of the device under measurement 200, φ₀ represents the initial phase of the carrier signal in the model of the device under measurement 200, G_{A}(ω₀) represents the signal component of the angular frequency ω₀ in a predetermined signal (detection signal) input to the model of the device under measurement 200, and H_{I}(ω₀) represents the angular frequency ω₀ component of the filter characteristic of the I-signal path when the frequency characteristic of the IQ error of the device under measurement 200 is expressed separately as the filter component of the I-signal path and the filter component of the Q-signal path. These values are represented in the same manner in Expressions 111 to 126.

The ideal signal calculating section 32 calculates the component A(ω₀) of the angular frequency ω₀ in the ideal signal using Expression 111. The ideal signal calculating section 32 calculates the value of Expression 111 for each of a plurality of frequencies, i.e. the sub-carriers, and outputs the calculated value at each frequency as the ideal signal.

FIG. 7 shows an angular frequency ω₀ component of a prediction signal calculated by the prediction signal calculating section 34. The prediction signal is affected by the IQ error of the device under measurement 200. Accordingly, the component A′(ω₀) of a given angular frequency ω₀ in the prediction signal affects the DC-symmetric mirror angular frequency (−ω₀) and is also affected by the mirror angular frequency (−ω₀). Accordingly, the component A′(ω₀) of a given angular frequency ω₀ in the prediction signal is a signal that is the sum of a component (positive component) corresponding to the signal component G_{A}(ω₀) of the angular frequency ω₀ in the predetermined signal (detection signal) and a component (negative component) corresponding to the signal component G_{B}(−ω₀) of the DC-symmetric mirror angular frequency (−ω₀) of the angular frequency ω₀ in the predetermined signal (detection signal).

Here, the positive component of the angular frequency ω₀ is shown below in Expression 112.

$$\frac{{M}_{0} \cdot {e}^{j {ϕ}_{0}}}{4} \cdot {G}_{A} ( {ω}_{0} ) \cdot {H}_{I} ( {ω}_{0} ) ( 1 + \frac{{H}_{Q} ( {ω}_{0} )}{{H}_{I} ( {ω}_{0} )} \cdot {e}^{j θ} ) \qquad ( 112 )$$

Here, H_{Q}(ω₀) represents the angular frequency ω₀ component of the filter characteristic of the Q-signal path when the frequency characteristic of the IQ error of the device under measurement 200 is expressed separately as the filter component of the I-signal path and the filter component of the Q-signal path, and θ represents the carrier phase error between I and Q of the device under measurement 200. These values are represented in the same manner in Expressions 111 to 126.

Specifically, the positive component of the angular frequency ω₀ is obtained by adding together (i) a value obtained as the product of the signal component G_{A}(ω₀) of the angular frequency ω₀ in the predetermined signal (detection signal) and the component H_{I}(ω₀) of the angular frequency ω₀ of the filter characteristic of the I-signal path and (ii) a value obtained as the product of the signal component G_{A}(ω₀) of the angular frequency ω₀ in the detection signal, the component H_{Q}(ω₀) of the angular frequency ω₀ of the filter characteristic of the Q-signal path, and the phase e^{jθ} of the carrier phase difference, and then multiplying the result of this addition by a value obtained as the product of a value (M₀/4) corresponding to the gain of the modulated signal and the initial phase e^{jθ0} of the carrier signal.

The negative component of the angular frequency ω₀ is shown below in Expression 113.

$$\frac{{M}_{0} \cdot {e}^{j {ϕ}_{0}}}{4} \cdot {G}_{B} ( - {ω}_{0} ) \cdot {H}_{I}^{*} ( {ω}_{0} ) ( 1 - \frac{{H}_{Q}^{*} ( {ω}_{0} )}{{H}_{I}^{*} ( {ω}_{0} )} \cdot {e}^{jθ} ) \qquad ( 113 )$$

Here, G_{B}(−ω₀) represents the signal component of the angular frequency −ω₀ in the predetermined signal (detection signal) input to the model of the device under measurement 200, H_{I}*(ω₀) represents the complex conjugate of the angular frequency ω₀ component of the filter characteristic of the I-signal path in the device under measurement 200, and H_{Q}*(ω₀) represents the complex conjugate of the angular frequency ω₀ component of the filter characteristic of the Q-signal path in the device under measurement 200. These values are represented in the same manner in Expressions 111 to 126.

Specifically, the negative component of the angular frequency ω₀ is obtained by adding together (i) a value obtained as the product of the signal component G_{B}(−ω₀) of the angular frequency −ω₀ in the predetermined signal (detection signal) and the complex conjugate H_{I}*(ω₀) of the angular frequency ω₀ component of the filter characteristic of the I-signal path and (ii) a value obtained as the product of the signal component G_{B}(−ω₀) of the angular frequency −ω₀ in the detection signal, the complex conjugate H_{Q}*(ω₀) of the angular frequency ω₀ component of the filter characteristic of the Q-signal path, and the phase e^{jθ} representing the carrier phase difference, and then multiplying the result of this addition by a value obtained as the product of a value (M₀/4) corresponding to the gain of the modulated signal and the initial phase e^{jθ0} of the carrier signal.

The component A′(ω₀) of the angular frequency ω₀ in the prediction signal is obtained by adding together the positive component represented by Expression 112 and the negative opponent represented by Expression 113. In other words, the component A′(ω₀) of the angular frequency ω₀ in the prediction signal is expressed as shown below in Expression 114.

$${A}_{1}^{′} ( {ω}_{0} ) = \frac{{M}_{0} \cdot {e}^{j {ϕ}_{0}}}{4} \{ \begin{matrix}{G}_{A} ( {ω}_{0} ) \cdot {H}_{I} ( {ω}_{0} ) ( 1 + \frac{{H}_{Q} ( {ω}_{0} )}{{H}_{I} ( {ω}_{0} )} \cdot {e}^{j θ} ) + \\ {G}_{B} ( - {ω}_{0} ) \cdot {H}_{I}^{*} ( {ω}_{0} ) ( 1 - \frac{{H}_{Q}^{*} ( {ω}_{0} )}{{H}_{I}^{*} ( {ω}_{0} )} \cdot {e}^{j θ} )\end{matrix} \} \qquad ( 114 )$$

The prediction signal calculating section 34 calculates the prediction signal as shown in Expression 114. Specifically, for each of a plurality of frequencies, the prediction signal calculating section 34 calculates the prediction signal corresponding to a signal that is the sum of (i) a component obtained as the product of the signal component G_{A}(ω₀) for this frequency in the predetermined signal and the frequency component H(ω) for the frequency characteristic of the IQ error and (ii) a component obtained as the product of the signal component G_{B}(ω₀) of the mirror frequency for this frequency in the predetermined signal and the complex conjugate H*(ω) of the frequency component for the frequency characteristic of the IQ error.

The EVM calculating section 36 calculates, as the EVM, a value corresponding to the root mean square of the constellation distance (error) between the ideal signal and the prediction signal for each of the frequencies, i.e. sub-carriers, based on the prediction signal calculated according to Expression 114 and the ideal signal calculated according to Expression 111. In the manner described above, the error amount calculating section 30 can calculate the EVM of the device under measurement 200.

In the present embodiment, the error amount calculating section 30 performs the computations of the ideal signal calculating section 32, the prediction signal calculating section 34, and the EVM calculating section 36 in a group. In this case, the error amount calculating section 30 calculates the EVM according to Expression 115 shown below. In Expression 115, in order to use the filter characteristic of the I-signal path as a reference, the filter characteristic H_{I}(ωₖ) of the I-signal path in the ideal signal is set to 1.

$$EVM = {C}_{1} \cdot \sqrt{\frac{{\sum }_{k = 1}^{ToneNum} {\vert \frac{{M}_{0} \cdot {e}^{j {ϕ}_{0}}}{4} \{ \begin{matrix}{G}_{A} ( {ω}_{k} ) + ( {H}_{I} ( {ω}_{k} ) + {H}_{Q} ( {ω}_{k} ) \cdot {e}^{j θ} ) + \\ \begin{matrix}{G}_{B} ( - {ω}_{k} ) ( {H}_{I}^{*} ( {ω}_{k} ) - {H}_{Q}^{*} ( {ω}_{k} ) \cdot {e}^{j θ} ) - \\ 2 {G}_{A} ( {ω}_{k} )\end{matrix}\end{matrix} \} \vert}^{2}}{ToneNum \cdot \vert \frac{{M}_{0} \cdot {e}^{j {ϕ}_{0}}}{4} \vert}} = {C}_{1} \cdot \sqrt{\frac{{\sum }_{k = 1}^{ToneNum} {\vert \{ \begin{matrix}{G}_{A} ( {ω}_{k} ) ( \begin{matrix}{H}_{I} ( {ω}_{k} ) + \\ {H}_{Q} ( {ω}_{k} ) \cdot {e}^{j θ}\end{matrix} ) + \\ \begin{matrix}{G}_{B} ( - {ω}_{k} ) ( \begin{matrix}{H}_{I}^{*} ( {ω}_{k} ) - \\ {H}_{Q}^{*} ( {ω}_{k} ) \cdot {e}^{j θ}\end{matrix} ) - \\ 2 {G}_{A} ( {ω}_{k} )\end{matrix}\end{matrix} \} \vert}^{2}}{ToneNum}} \qquad ( 115 )$$

Here, ToneNum represents the number of sub-carriers in the OFDM signal, k represents the sub-carrier number for identifying each sub-carrier in the OFDM signal, G_{A}(ωₖ) represents the signal component of the sub-carrier k in the predetermined signal input to the model of the device under measurement 200, G_{B}(−ωₖ) represents the signal component of the mirror sub-carrier −k of the sub-carrier k in the predetermined signal input to the model of the device under measurement 200, H_{I}(ωₖ) represents the angular frequency ωₖ component of the filter characteristic of the I-signal path when the frequency characteristic of the IQ error is expressed separately as the filter component of the I-signal path and the filter component of the Q-signal path, H_{Q}(ωₖ) represents the angular frequency ωₖ component of the filter characteristic of the Q-signal path, H_{I}*(ωₖ) represents the complex conjugate of the angular frequency ωₖ component of the filter characteristic of the I-signal path, H_{Q}*(ωₖ) represents the complex conjugate of the angular frequency ωₖ component of the filter characteristic of the Q-signal path, and C₁ represents a constant determined according to the standard of the OFDM signal. These values are represented in the same manner in Expressions 111 to 126.

Furthermore, the error amount calculating section 30 may calculate the root mean square of Expression 115 for each of the symbols of the OFDM signal, and may calculate the average of the calculated root mean squares as the EVM. As a result, the error amount calculating section 30 can calculate the EVM of the device under measurement 200 when a detection signal with a plurality of symbols is input.

The error amount calculating section 30 may calculate the EVM by substituting the average value of the signal components of the plurality of symbols for G_{A}(ωₖ) and G_{B}(−ωₖ) in Expression 115, for each sub-carrier. In this way as well, the error amount calculating section 30 can calculate the EVM of the device under measurement 200 when a detection signal with a plurality of symbols is input.

In the manner described above, the measurement apparatus 10 of the present embodiment can easily calculate the EVM of the device under measurement 200 that modulates or demodulates an OFDM signal.

In an OFDM signal communication system, channel characteristics are corrected by transmitting a modulated signal that includes a reference signal of predetermined signal points, such as a pilot signal. In the communication standards for each OFDM signals, there are cases where the standards dictate that the EVM be measured in a state where the channel characteristics have been corrected using a reference signal.

Therefore, when measuring the EVM of an OFDM signal compliant with such standards, the error amount calculating section 30 calculates the EVM using Expression 116 shown below.

$$EVM = {C}_{1} \cdot \sqrt{\frac{{\sum }_{k = 1}^{ToneNum} {\vert \begin{matrix}\{ \begin{matrix}{G}_{A} ( {ω}_{k} ) ( {H}_{I} ( {ω}_{k} ) + {H}_{Q} ( {ω}_{k} ) \cdot {e}^{j θ} ) \cdot \\ C ( {ω}_{k} ) + {G}_{B} ( - {ω}_{k} ) ( \begin{matrix}{H}_{I}^{*} ( {ω}_{k} ) - \\ {H}_{Q}^{*} ( {ω}_{k} ) \cdot {e}^{j θ}\end{matrix} ) \cdot C ( {ω}_{k} )\end{matrix} \} - \\ 2 {G}_{A} ( {ω}_{k} )\end{matrix} \vert}^{2}}{ToneNum}} \qquad ( 116 )$$

Here, C(ωₖ) represents the angular frequency (ωₖ) component of the correction characteristic when correcting the channel characteristic.

More specifically, the error amount calculating section 30 calculates the correction coefficient C(ωₖ) corresponding to the channel characteristic calculated based on the IQ error for the signal component of each frequency in the prediction signal. Next, for each of the frequencies, the error amount calculating section 30 calculates the error by subtracting an ideal signal from the prediction signal that has been multiplied by the correction coefficient C(ωₖ). The error amount calculating section 30 then calculates, as the EVM, the root mean square of the error calculated for each of the frequencies. In this way, the error amount calculating section 30 can calculate the EVM in a state where the channel characteristic has been corrected using a reference signal.

For example, a wireless LAN (Local Area Network) standard such as IEEE802.11 is known as a standard in which the EVM is measured in a state where the channel characteristic has been corrected using a reference signal. For this standard, there is a sub-carrier that includes a reference signal for expressing the channel characteristic of only the I channel and a sub-carrier that includes a reference signal for expressing the channel characteristic of only the Q channel.

Accordingly, in the case of a wireless LAN standard such as IEEE802.11, since the filter characteristic of the I-signal path is used as a reference, the error amount calculating section 30 sets a value of 1 for the component C(ωₖ) of the sub-carrier k of the correction coefficient for correcting the channel characteristic of only the I channel. The error amount calculating section 30 sets the component C(ωₖ) of the sub-carrier k of the correction coefficient for correcting the channel characteristic of only the Q channel to be {H_{I}(ωₖ)/(H_{Q}(ωₖ)·e^{jθ})}. In this way, the error amount calculating section 30 calculates the correction coefficient C(ωₖ) expressing the channel characteristic calculated based on the IQ error {H_{I}(ωₖ)/(H_{Q}(ωₖ)·e^{jθ})} for the signal component of each frequency in the prediction signal. Therefore, the error amount calculating section 30 can calculate the EVM corresponding to the wireless LAN standard such as IEEE 802.11.

Furthermore, the IEEE 802.16e wireless MAN (Metropolitan Area Network) is another known standard for which the EVM is measured in a state where the channel characteristic has been corrected. For IEEE 802.16e, the reference signal is inserted into sub-carriers arranged discretely within the data signal, without using a preamble in the uplink. Because of this, for IEEE 802.16e, the EVM must be corrected by calculating the channel characteristic for all of the sub-carriers by using not only the reference signal, but also the data.

Accordingly, in the case of the IEEE 802.16e wireless LAN standard, the error amount calculating section 30 calculates the correction coefficient C(ωₖ) for correcting the channel characteristic as shown below in Expression 117.

$$\begin{matrix}C ( {ω}_{k} ) = \frac{{R}_{A} ( {ω}_{k} )}{\begin{matrix}\frac{{R}_{A} ( {ω}_{k} )}{2} ( {H}_{I} ( {ω}_{k} ) + {H}_{Q} ( {ω}_{k} ) {e}^{jθ} ) + \\ \frac{{R}_{B} ( {ω}_{k} )}{2} ( {H}_{I} ( {ω}_{k} ) - {H}_{Q} ( {ω}_{k} ) {e}^{j θ} )\end{matrix}} \\ = \frac{2}{\begin{matrix}( {H}_{I} ( {ω}_{k} ) + {H}_{Q} ( {ω}_{k} ) {e}^{j θ} ) + \\ δ ( {H}_{I} ( {ω}_{k} ) - {H}_{Q} ( {ω}_{k} ) {e}^{j θ} )\end{matrix}} \\ = \frac{2}{{H}_{I} ( {ω}_{k} ) \{ \begin{matrix}( 1 + {IQ}_{imbalance} ( {ω}_{k} ) ) + \\ δ ( 1 - {IQ}_{imbalance} ( {ω}_{k} ) )\end{matrix} \}}\end{matrix} \qquad ( 117 )$$

In Expression 117, R_{A}(ωₖ) represents the signal component of the reference signal of the sub-carrier k, R_{B}(ωₖ) represents the mirror signal component applied to the sub-carrier k by the reference signal of the sub-carrier (−k) that is DC symmetric to the sub-carrier k, δ represents R_{A}(ωₖ)/R_{B}(ωₖ), and IQ_{imbalance} represents {H_{I}(ωₖ)/(H_{Q}(ωₖ)·e^{jθ})}

In this way, the error amount calculating section 30 calculates the correction coefficient based on the signal component (R_{A}(ωₖ)) of the reference signal of the frequency, the signal component (R_{B}(ωₖ)) provided to this frequency by the reference signal of the mirror frequency, and the IQ error (IQ_{imbalance}(ωₖ)). As a result, even when calculating the EVM using data in addition to the reference signal, the error amount calculating section 30 can multiply the signal component of each of the frequencies in the prediction signal by the correction coefficient C(ωₖ) representing the channel characteristic calculated based on the IQ error {H_{I}(ωₖ)/(H_{Q}(ωₖ)·e^{jθ})}. Accordingly, the error amount calculating section 30 can calculate the EVM corresponding to a wireless LAN standard such as IEEE 802.16e.

There are cases in which the difference between the filter characteristic (H_{I}(ωₖ)) of the I-signal path and the filter characteristic (H_{Q}(ωₖ)) of the Q-signal path is less than a predetermined value and H_{I}(ωₖ)−H_{Q}(ωₖ)≈0. In such a case, the error amount calculating section 30 may calculate the correction coefficient C(ωₖ) based on the IQ error and the frequency component of the filter characteristic of the I-signal path, as shown in Expression 118 below.

$$\begin{matrix}C ( {ω}_{k} ) = \frac{2}{( {H}_{I} ( {ω}_{k} ) + {H}_{Q} ( {ω}_{k} ) {e}^{j θ} )} \\ = \frac{2}{{H}_{I} ( {ω}_{k} ) ( 1 + {IQ}_{imbalance} ( {ω}_{k} ) )}\end{matrix} \qquad ( 118 )$$

In this way, the error amount calculating section 30 can calculate the correction coefficient without using the signal component of the reference signal, and can therefore use a simple calculation.

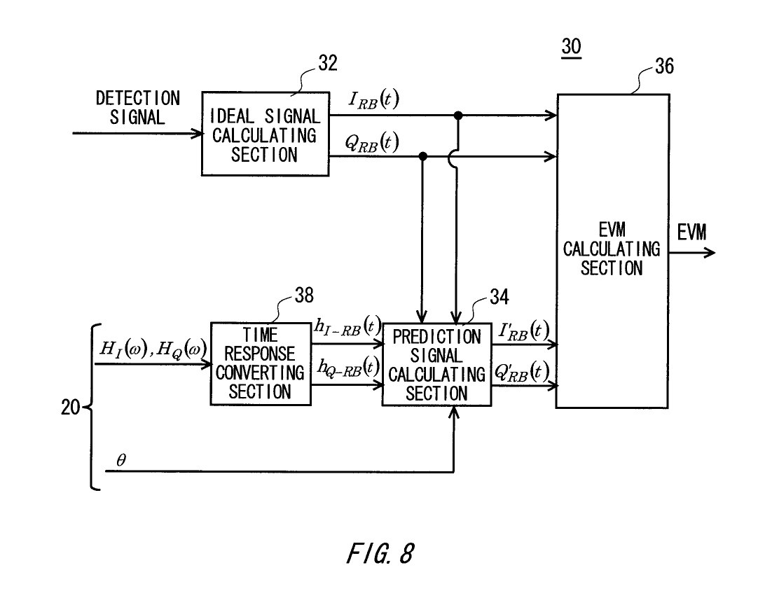

FIG. 8 shows a configuration of an error amount calculating section 30 that calculates the EVM of a device under measurement 200 that modulates or demodulates SC-FDMA (Single-Carrier Frequency Division Multiple Access) signals. When the EVM of a device under measurement 200 that modulates or demodulates SC-FDMA signals is to be calculated, the error amount calculating section 30 includes an ideal signal calculating section 32, an EVM calculating section 36, a time response converting section 38, and a prediction signal calculating section 34.

The ideal signal calculating section 32 calculates the I component and the Q component of an ideal signal expressed in the time domain, for each of a plurality of resource blocks in a determined multiplexing frequency range in the SC-FDMA signal. For example, the ideal signal calculating section 32 may calculate the calculate the I component and the Q component of the ideal signal expressed in the time domain that are to be output in response to the input, into an ideal model of the device under measurement 200 that does not include an IQ error, a detection signal for calculating the EVM as defined by the communication standard (e.g. LTE) using the SC-FDMA signal. Furthermore, the ideal signal calculating section 32 may calculate, for a plurality of symbols, the I component and Q component of the ideal signal expressed in the time domain.

The time response converting section 38 calculates the impulse response of the filter characteristic of the I-signal path and the impulse response of the filter characteristic of the Q-signal path in a case where the frequency characteristic of the IQ error is represented separately as the filter characteristic of the I-signal path and the filter characteristic of the Q-signal path, for each of the resource blocks.

The prediction signal calculating section 34 calculates the I component of the prediction signal expressed in the time domain for each resource block, by calculating the convolution integral of the I component of the ideal signal in the time domain and the impulse response of the filter characteristic of the I-signal path. Furthermore, the prediction signal calculating section 34 calculates the Q component of the prediction signal expressed in the time domain for each resource block, by calculating the convolution integral of the Q component of the ideal signal in the time domain and the impulse response of the filter characteristic of the Q-signal path. The prediction signal calculating section 34 may calculate the I component and the Q component of the prediction signal expressed in the time domain for each of a plurality of sub-symbols.

The EVM calculating section 36 calculates, as the EVM, the root mean square of the constellation error (distance) between the prediction signal and the ideal signal for each resource block. The EVM calculating section 36 may output, as the EVM, the average value of the root mean squares calculated for the plurality of sub-symbols.

The error amount calculating section 30 described above can calculate the EVM without needing to measure the output signal resulting from the actual input of an SC-FDMA signal in compliance with a standard into the device under measurement 200. Therefore, the measurement apparatus 10 can calculate the EVM of the device under measurement 200 that modulates or demodulates an SC-FDMA signal in a short time using a simple process.

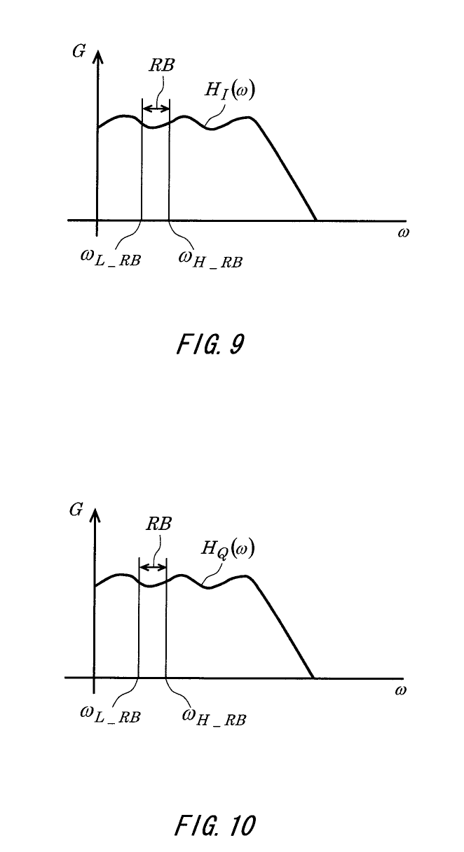

FIG. 9 shows an exemplary filter characteristic (H_{I}(ω)) of the I-signal path of the device under measurement 200. FIG. 10 shows an exemplary filter characteristic (H_{Q}(ω)) of the Q-signal path of the device under measurement 200.

In the communication standard for transmitting SC-FDMA signals, a resource block is a unit obtained by partitioning the transmission channel in a frequency direction and a time direction. With the communication standard for transmitting SC-FDMA signals, when a plurality of users share a transmission channel, the usable transmission paths are allocated in resource block units.

The time response converting section 38 performs an inverse Fourier transform as shown in Expression 121 on the frequency characteristic H_{I}(ω) of the I-signal path of the device under measurement 200, for each resource block, to calculate the impulse response h_{I}_{_{—}}_{RB}(t) of the filter characteristic of the I-signal path of the device under measurement 200.

$${h}_{I \_ RB} ( t ) = {\int }_{{ω}_{L \_ RB}}^{{ω}_{H \_ RB}} {H}_{I} ( ω ) \cdot {e}^{j ω t} d ω \qquad ( 121 )$$

Here, t represents the time, RB represents the resource block number for identifying a resource block included in the SC-FDMA signal, h_{I}_{_{—}}_{RB}(t) represents the impulse response of the resource block RB of the filter characteristic of the I-signal path in the device under measurement 200, ω_{H}_{_{—}}_{RB} represents the angular frequency of the top end of the resource block RB, and ω_{L}_{_{—}}_{RB} represents the angular frequency of the bottom end of the resource block RB. These values are represented in the same manner in Expressions 111 to 126.

In the same manner, the time response converting section 38 performs an inverse Fourier transform as shown in Expression 122 on the frequency characteristic H_{Q}(ω) of the Q-signal path of the device under measurement 200, for each resource block, to calculate the impulse response h_{Q}_{_{—}}_{RB}(t) of the filter characteristic of the Q-signal path of the device under measurement 200.

$${h}_{Q \_ RB} ( t ) = {\int }_{{ω}_{L \_ RB}}^{{ω}_{H \_ RB}} {H}_{Q} ( ω ) \cdot {e}^{j ω t} d ω \qquad ( 122 )$$

Here, h_{Q}_{_{—}}_{RB}(t) represents the impulse response of the resource block RB of the filter characteristic of the Q-signal path in the device under measurement 200. This value is represented in the same manner in Expressions 111 to 126.

The time response converting section 38 may calculate the impulse response together for a plurality of adjacent resource blocks. In this case, the ideal signal calculating section 32 generates the I component and the Q component of the ideal signal in the time domain for each range corresponding to a frequency range of the impulse response calculated by the time response converting section 38.

The prediction signal calculating section 34 calculates the I component of the prediction signal and the Q component of the prediction signal for each resource block, using Expression 123.

$$( \begin{matrix}{I}_{RB}^{′} ( t ) \\ {Q}_{RB}^{′} ( t )\end{matrix} ) = ( \begin{matrix}cos ( θ ) & sin ( θ ) \\ sin ( θ ) & cos ( θ )\end{matrix} ) ( \begin{matrix}{I}_{RB} ( t ) * {h}_{I \_ RB} ( t ) \\ {Q}_{RB} ( t ) * {h}_{Q \_ RB} ( t )\end{matrix} ) \qquad ( 123 )$$

In Expression 123, * represents the convolution integral computation, I_{RB}(t) represents the I component of the ideal signal, Q_{RB}(t) represents the Q component of the ideal signal, I′_{RB}(t) represents the I component of the prediction signal, and Q′_{RB}(t) represents the Q component of the prediction signal. These values are represented in the same manner in Expressions 111 to 126.

Specifically, for each resource block, the prediction signal calculating section 34 calculates the I component I′_{RB}(t) of the prediction signal expressed in the time domain by computing the convolution integral of the I component I_{RB}(t) of the ideal signal in the time domain and the impulse response h_{I}_{_{—}}_{RB}(t) of the filter characteristic of the I-signal path. The prediction signal calculating section 34 calculates the Q component Q′_{RB}(t) of the prediction signal expressed in the time domain by computing the convolution integral of the Q component Q_{RB}(t) of the ideal signal in the time domain and the impulse response h_{Q}_{_{—}}_{RB}(t) of the filter characteristic of the Q-signal path. Furthermore, the prediction signal calculating section 34 corrects the phases of the I component of the prediction signal expressed in the time domain and the Q component of the prediction signal expressed in the time domain, by the carrier phase error θ of the device under measurement 200.

The EVM calculating section 36 calculates, as the EVM, the root mean square of the constellation error (distance) between the prediction signal and the ideal signal, for each of the resource blocks. Specifically, the EVM calculating section 36 calculates the EVM using Expression 124.

$$EVM = {C}_{2} \cdot \sqrt{{\sum }_{RB = 1}^{RBUM} \frac{{( {I}_{RB}^{′} ( t ) - {I}_{RB} ( t ) )}^{2} + {( {Q}_{RB}^{′} ( t ) - {Q}_{RB} ( t ) )}^{2}}{{( {I}_{RB} ( t ) + {Q}_{RB} ( t ) )}^{2}}} \qquad ( 124 )$$

Here, RBNUM represents the number of resource blocks included in the SC-FDMA signal, and C₂ represents a constant that is determined according to the standard of the SC-FDMA signal. These values are represented in the same manner in Expressions 111 to 126.

As shown above, the measurement apparatus 10 of the present embodiment can easily calculate the EVM of the device under measurement 200 that modulates or demodulates the SC-FDMA signal.

Furthermore, with the configuration shown in FIG. 8, the error amount calculating section 30 can calculate the EVM of the device under measurement 200 that modulates or demodulates QAM (Quadrature Amplitude Modulation) signals. In this case, the error amount calculating section 30 performs the same process as is performed when calculating the EVM of a device under measurement 200 that modulates or demodulates an SC-FDMA signal in which there is only one resource block in the frequency direction.

In other words, in this case, the ideal signal calculating section 32 calculates the I component and the Q component of the ideal signal expressed in the time domain within the frequency range of the QAM signal.

The time response converting section 38 calculates the impulse response of the filter characteristic of the I-signal path and the impulse response of the filter characteristic of the Q-signal path in the frequency range of the QAM signal. More specifically, the time response converting section 38 calculates the impulse response of the filter characteristic of the I-signal path using Expression 121. The time response converting section 38 calculates the impulse response of the filter characteristic of the Q-signal path using Expression 122. In Expressions 121 and 122, ω_{H}_{_{—}}_{RB} is the angular frequency of the top end of the frequency range of the QAM signal and ω_{L}_{_{—}}_{RB} is the angular frequency of the bottom end of the frequency range of the QAM signal.

The prediction signal calculating section 34 calculates the I component of the prediction signal expressed in the time domain by computing the convolution integral of the I component of the ideal signal in the time domain and the impulse response of the filter characteristic of the I-signal path, within the frequency range of the QAM signal. Furthermore, the prediction signal calculating section 34 calculates the Q component of the prediction signal expressed in the time domain by computing the convolution integral of the Q component of the ideal signal in the time domain and the impulse response of the filter characteristic of the Q-signal path, within the frequency range of the QAM signal.

The EVM calculating section 36 calculates, as the EVM, the root mean square of the constellation error between the prediction signal and the ideal signal calculated in the above manner. In other words, the EVM calculating section 36 calculates the EVM using Expression 125 shown below.

$$EVM = {C}_{3} \cdot \sqrt{\frac{{( {I}^{′} ( t ) - I ( t ) )}^{2} + {( {Q}^{′} ( t ) - Q ( t ) )}^{2}}{{( I ( t ) + Q ( t ) )}^{2}}} \qquad ( 125 )$$

Here, I(t) represents the I component of the ideal signal, Q(t) represents the Q component of the ideal signal, I′(t) represents the I component of the prediction signal, Q′(t) represents the Q component of the prediction signal, and C₃ represents a constant determined according to the standard of the QAM signal.

In the manner described above, the measurement apparatus 10 of the present embodiment can easily calculate the EVM of a device under measurement 200 that modulates or demodulates a QAM signal.

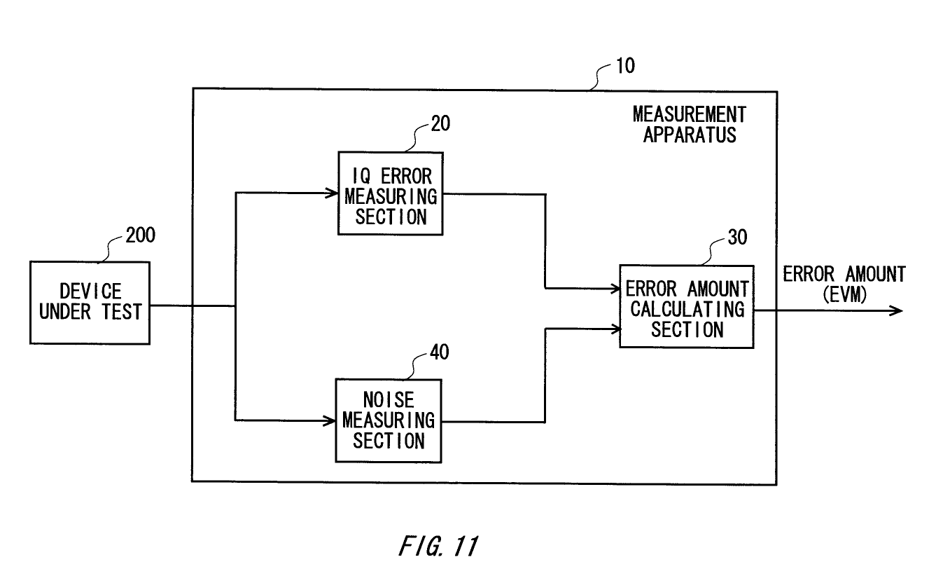

FIG. 11 shows a configuration of a modification of the measurement apparatus 10 according to the present embodiment, along with the device under measurement 200. The measurement apparatus 10 may further include a noise measuring section 40. In the device under measurement 200, phase noise is superimposed on the carrier signal. Furthermore, the device under measurement 200 also includes overall random jitter. The device under measurement 200 outputs a signal that includes noise resulting from the effects of such phase noise and random noise, for example. The noise measuring section 40 measures the signal-to-noise ratio (S/N ratio) of the output signal of the device under measurement 200.

The error amount calculating section 30 calculates an EVM that reflects the noise component, when the noise measuring section 40 has measured the S/N ratio of the device under measurement 200. More specifically, the error amount calculating section 30 calculates the EVM as shown in Expression 126 below. In Expression 126, σ represents the S/N ratio measured by the noise measuring section 40.

$$EVM = {C}_{1} \cdot \sqrt{{σ}^{2} + \frac{{\sum }_{k = 1}^{ToneNum} {\vert \{ \begin{matrix}( \begin{matrix}{G}_{A} ( {ω}_{k} ) ( {H}_{I} ( {ω}_{k} ) + {H}_{Q} ( {ω}_{k} ) \cdot {e}^{j θ} ) + \\ {G}_{B} ( {ω}_{k} ) ( {H}_{I}^{*} ( {ω}_{k} ) - {H}_{Q}^{*} ( {ω}_{k} ) \cdot {e}^{j θ} )\end{matrix} ) \cdot \\ C ( {ω}_{k} ) - 2 {G}_{A} ( {ω}_{k} )\end{matrix} \} \vert}^{2}}{ToneNum}} \qquad ( 126 )$$

In other words, the error amount calculating section 30 calculates, as the EVM, the square root of a value obtained as the sum of the square of the S/N ratio (σ²) and the square of the constellation error between the prediction signal and the ideal signal. In the manner described above, the measurement apparatus 10 of the present modification can easily measure the EVM that reflects the effect of noise, such as phase noise and random noise, included in the device under measurement 200.

FIG. 12 shows a configuration of the IQ error measuring section 20 according to the present embodiment, along with a quadrature modulator 300. The IQ error measuring section 20 measures the carrier phase error, the frequency characteristic of the gain error, and the frequency characteristic of the IQ phase error of the quadrature modulator 300, which is a device under measurement 200.

The IQ error measuring section 20 includes a supplying section 112, a frequency shifting section 114, a bypass switch 116, a sampling section 118, an extracting section 120, a calculating section 122, an adjustment combining section 124, an I-side output switching section 126, a Q-side output switching section 128, an input switching section 130, and an adjusting section 132.

The supplying section 112 shifts a reference I signal corresponding to an I component of an IQ signal causing a tone signal and/or a reference Q signal corresponding to a Q component of this IQ signal to create a time difference therebetween, and supplies the resulting I signal and Q signal to the quadrature modulator 300. In this case, the supplying section 112 supplies the reference I signal to an I-signal input port of the quadrature modulator 300 and supplies the reference Q signal to a Q-signal input port of the quadrature modulator 300.

In the present embodiment, the supplying section 112 shifts a reference I signal and/or a reference Q signal corresponding to an IQ signal causing a multi-tone signal with either a positive frequency or a negative frequency to have a time difference therebetween, and supplies the resulting signals to the quadrature modulator 300. The multi-tone signal refers to a modulated signal that includes tone signals with a plurality of frequencies ω₁, ω₂, ω₃, . . . , ωₖ, where k is a natural number. Instead, the supplying section 112 may supply the quadrature modulator 300 with a reference I signal and a reference Q signal corresponding to an IQ signal that causes a monotone signal, i.e. a modulated signal including a tone signal with only one frequency. Furthermore, positive frequency refers to a frequency that is higher than the carrier frequency of the modulated signal and negative frequency refers to a frequency that is lower than the carrier frequency of the modulated signal.

The supplying section 112 may include a waveform generating section 142, an I-side DAC 144, and a Q-side DAC 146. The waveform generating section 142 generates the waveform data of the reference I signal and the waveform data of the reference Q signal with a time difference therebetween.

The waveform generating section 142 may output, as the waveform data of the reference I signal, data indicating a waveform obtained as the total of sinusoidal waves, e.g. cosine waves, having predetermined frequencies and predetermined phases. The waveform generating section 142 may output, as the waveform data of the reference Q signal, data indicating a waveform obtained as the total of sinusoidal waves with phases differing by 90 degrees from the reference I signal, e.g. sine waves.

The waveform generating section 142 supplies the waveform data of the reference I signal described above to the I-side DAC 144. The waveform generating section 142 supplies the waveform data of the reference Q signal described above to the Q-side DAC 146.

The I-side DAC 144 performs DA conversion on the waveform data of the reference I signal supplied from the waveform generating section 142, and supplies the result to the I-signal input terminal of the quadrature modulator 300. The Q-side DAC 146 performs DA conversion of the waveform data of the reference Q signal supplied from the waveform generating section 142, and supplies the result to the Q-signal input terminal of the quadrature modulator 300.

In the manner described above, the supplying section 112 can shift the reference I signal and/or the reference Q signal to have a time difference therebetween, and supply the resulting signals to the quadrature modulator 300. In response to the reference I signal being supplied thereto, the quadrature modulator 300 can output a modulated signal obtained by modulating the reference I signal with the I component of the carrier signal and modulating a zero-amplitude Q signal by the Q component of the carrier signal. Furthermore, in response to the reference Q signal being supplied thereto, the quadrature modulator 300 can output a modulated signal obtained by modulating a zero-amplitude I signal by the I component of the carrier signal and modulating the reference Q signal by the Q component of the carrier signal.

The frequency shifting section 114 down-converts the carrier frequency of the modulated signal output by the quadrature modulator 300 to an intermediate frequency, and supplies the resulting signal to the sampling section 118. If the down conversion by the frequency shifting section 114 is unnecessary, the bypass switch 116 causes the modulated signal output from the quadrature modulator 300 to bypass the frequency shifting section 114 and be supplied to the sampling section 118.

The sampling section 118 samples and digitizes the modulated signal output from the frequency shifting section 114. If the down conversion by the frequency shifting section 114 is unnecessary, the sampling section 118 directly samples and digitizes the modulated signal output from the quadrature modulator 300.

The extracting section 120 extracts the frequency component, i.e. the I-signal frequency component, corresponding to each tone signal included in the modulated signal output from the quadrature modulator 300 in response to the reference I signal supplied thereto. The extracting section 120 extracts the frequency component, i.e. the Q-signal frequency component, corresponding to each tone signal included in the modulated signal output from the quadrature modulator 300 in response to the reference Q signal supplied thereto. The extracting section 120 may extract the I-signal frequency component and the Q-signal frequency component, which are the frequency components corresponding to a tone signal, by performing a discrete Fourier transform, such as a fast Fourier transform, on the modulated signal digitized by the sampling section 118.

Here, the extracting section 120 extracts, as the frequency components corresponding to each tone signal, a signal component with the frequency of the tone signal and a signal component with a frequency positioned in a manner to sandwich the carrier frequency ω₀ with the frequency of the tone signal and to have the opposite sign of the frequency of the tone signal. If the frequency of the tone signal is ωₖ and the carrier frequency is ω₀, for example, the extracting section 120 extracts a signal component with a frequency ω₀+ωₖ and a signal component with a frequency ω₀−ωₖ.

The calculating section 122 calculates the frequency characteristic of the phase error and the frequency characteristic of the gain error of the quadrature modulator 300, based on the I-signal frequency component and the Q-signal frequency component extracted by the extracting section 120. The calculating section 122 may also calculate the carrier phase error of the quadrature modulator 300.

The extracting section 120 and calculating section 122 described above may be realized as a processor. The calculation method performed by the calculating section 122 is described in detail below.

At an adjustment time that is prior to the measurement of the IQ error, the adjustment combining section 124 combines an adjustment I signal and an adjustment Q signal output from the supplying section 112, and supplies the result to the sampling section 118.

The I-side output switching section 126 and the Q-side output switching section 128 switch the destination of the signals from the supplying section 112 according to the adjustment time and an IQ error measurement time. During the measurement time, the I-side output switching section 126 and the Q-side output switching section 128 supply the quadrature modulator 300 with the reference I signal and the reference Q signal output from the supplying section 112. During the adjustment time, the I-side output switching section 126 and the Q-side output switching section 128 supply the adjustment combining section 124 with the adjustment I signal and the adjustment Q signal output from the supplying section 112.

The input switching section 130 switches the input destination of the signal sampled by the sampling section 118 according to the IQ error measurement time and the adjustment time. During the measurement time, the input switching section 130 causes the modulated signal output from the quadrature modulator 300 to be sampled by the sampling section 118. During the adjustment time, the input switching section 130 causes the combined signal output from the adjustment combining section 124 to be sampled by the sampling section 118.

The adjusting section 132 adjusts the error, e.g. the frequency error, phase error, or gain error, of the reference I signal and the reference Q signal output by the supplying section 112. For example, the adjusting section 132 causes the supplying section 112 to output a predetermined adjustment I signal and a predetermined adjustment Q signal to be sampled by the sampling section 118. The adjusting section 132 adjusts the waveforms of the reference I signal and the reference Q signal output by the supplying section 112, based on the sampling results. For example, the adjusting section 132 may adjust the error between the reference I signal and the reference Q signal output by the supplying section 112 using the methods described in International Publication WO 2007/072653 or International Publication WO 2007/077686.

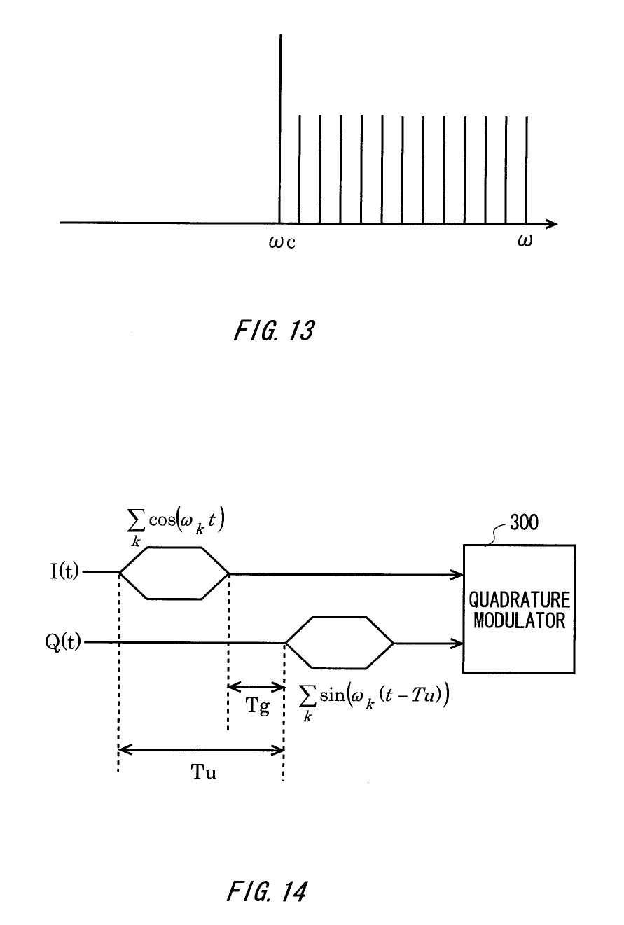

FIG. 13 shows an exemplary multi-tone signal output from an ideal quadrature modulator when the quadrature modulator is simultaneously supplied with a reference I signal and a reference Q signal. FIG. 14 shows exemplary timings at which the reference I signal and the reference Q signal are supplied to the quadrature modulator 300.

The supplying section 112 of the IQ error measuring section 20 outputs the reference I signal and the reference Q signal causing a multi-tone signal such as shown in FIG. 13. The supplying section 112 temporally shifts the waveform of the reference I signal and/or the waveform of the reference Q signal as shown in FIG. 14, such that these waveforms do not overlap, and supplies the quadrature modulator 300 with the resulting waveforms.

The supplying section 112 may shift the reference I signal and/or the reference Q signal to have a difference therebetween of a period Tu, which is longer then the time width of the waveform of the reference I signal (or the waveform of the reference Q signal), and supply resulting signals to the quadrature modulator 300. If a filter or the like is provided downstream from the quadrature modulator 300, the modulated signal output by the quadrature modulator 300 has a waveform that expands due to distortion or the like. Accordingly, the supplying section 112 preferably ensures a predetermined guard period Tg between the reference I signal and the reference Q signal.

The supplying section 112 preferably supplies the quadrature modulator 300 with the reference I signal and the reference Q signal in a continuous series without stopping the clock. As a result, the IQ error measuring section 20 can accurately extract the frequency characteristics of the reference I signal and the reference Q signal without correcting phase skew of the sampling clocks. Furthermore, the supplying section 112 may supply the quadrature modulator 300 with a signal that causes a single-tone signal for measuring the noise, e.g. S/N ratio or C/N ratio, continuously before or after the reference I signal and reference Q signal that cause the multi-tone signal. In this way, the IQ error measuring section 20 can perform the timing extraction process for analyzing the waveforms in common with both the noise measurement process and the IQ error measurement process, thereby decreasing the analysis process time.

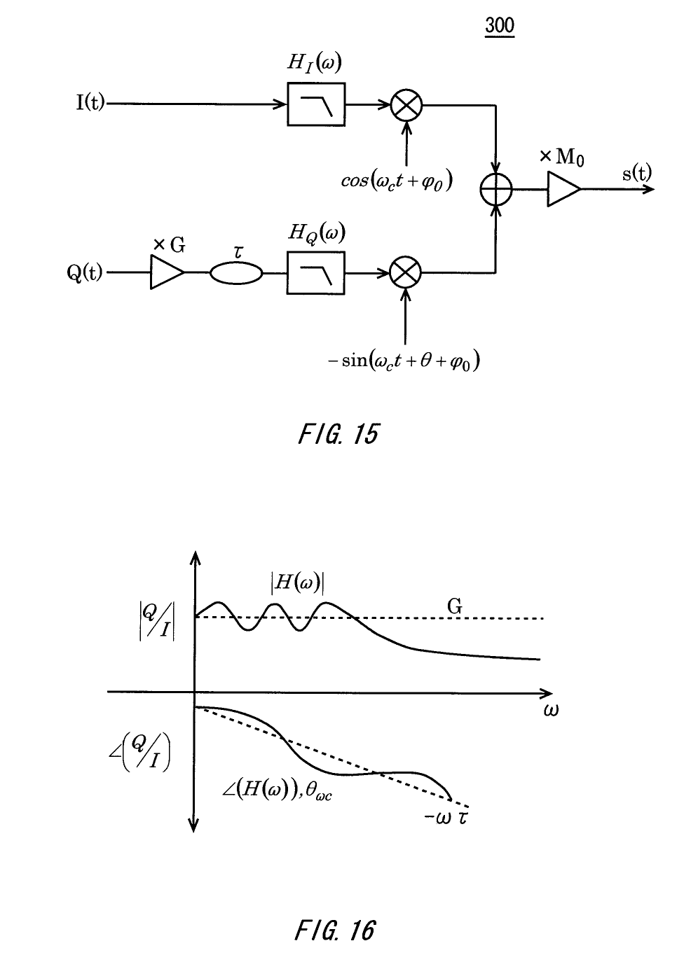

FIG. 15 shows an error model of the quadrature modulator 300. The following describes the error model of the quadrature modulator 300. The variables used in the description of the error model are shown below.

Here, t represents time, ω_{C} represents the carrier frequency, ω₀ represents the angular frequency of the signal input to the quadrature modulator 300, I(t) represents the time waveform of the I signal input to the quadrature modulator 300, Q(t) represents the time waveform of the Q signal input to the quadrature modulator 300, s(t) represents the time waveform of the modulated signal output from the quadrature modulator 300, H_{I}(ω) represents the filter characteristic of the I-signal path of the quadrature modulator 300 with respect to angular frequency w, H_{Q}(ω) represents the filter characteristic of the Q-signal path of the quadrature modulator 300 with respect to angular frequency ω, M₀ represents the gain of the quadrature modulator 300, G represents the gain error between I and Q of the quadrature modulator 300, τ represents the skew between I and Q of the quadrature modulator 300, θ and θω_{C} represent carrier phase errors of the quadrature modulator 300, and φ represents the initial phase of the carrier signal.

In the error model of FIG. 15, when H_{I}(ω), H_{Q}(ω), and τ are not considered, the modulated signal s(t) output from the quadrature modulator 300 is expressed as shown in Expression 1 below.

$$\begin{matrix}s ( t ) = {M}_{0} \cdot \{ I ( t ) \cdot cos ( {ω}_{c} t + {ϕ}_{0} ) - G \cdot Q ( t ) \cdot sin ( {ω}_{c} t + {ϕ}_{0} + θ ) \} \\ = {M}_{0} \cdot \{ \begin{matrix}( I ( t ) - Q ( t ) \cdot G \cdot sin ( θ ) ) \cdot cos ( {ω}_{c} t + {ϕ}_{0} ) - Q ( t ) \cdot G \cdot \\ cos ( θ ) \cdot sin ( {ω}_{c} t + {ϕ}_{0} )\end{matrix} \}\end{matrix} \qquad ( 1 )$$

When this modulated signal s(t) is demodulated by an ideal quadrature demodulator, the demodulated baseband signal R(t) is expressed as shown in Expression 2 below. The carrier phase error θ and the gain error G between I and Q are considered as being included on the Q-signal side.

$$\begin{matrix}\overline{R} ( t ) = \frac{{M}_{0} \cdot {e}^{j {ϕ}_{0}}}{2} \cdot \{ ( I ( t ) - Q ( t ) \cdot G \cdot sin ( θ ) ) + j \cdot Q ( t ) \cdot G \cdot cos ( θ ) \} \\ = \frac{{M}_{0} \cdot {e}^{j {ϕ}_{0}}}{2} \cdot \{ I ( t ) + j \cdot Q ( t ) \cdot G \cdot ( cos ( θ ) + j \cdot sin ( θ ) ) \} \\ = \frac{{M}_{0} \cdot {e}^{j {ϕ}_{0}}}{2} \cdot \{ I ( t ) + j \cdot Q ( t ) \cdot G \cdot {e}^{j θ} \}\end{matrix} \qquad ( 2 )$$

Next, it is assumed that the quadrature modulator 300 with a skew τ between I and Q is supplied with the reference I signal and the reference Q signal having angular frequencies of ω₀. The skew between I and Q is considered as being included on the Q-signal side.

In this case, the baseband signal demodulated by the ideal quadrature demodulator can be calculated by substituting cos(ω₀t) for I(t) and sin(ω₀(t−τ)) for Q(t) in Expression 2. The result of this is shown below in Expression 3.

$$\frac{{M}_{0} \cdot {e}^{j {ϕ}_{0}}}{2} \cdot \{ I ( t ) + j \cdot Q ( t ) \cdot G \cdot {e}^{j θ} \} = \frac{{M}_{0} \cdot {e}^{j {ϕ}_{0}}}{2} \cdot \{ \frac{{e}^{j {ω}_{0} t} + {e}^{- j {ω}_{0} t}}{2} + j \cdot \frac{{e}^{j {ω}_{0} ( t - τ )} - {e}^{- j {ω}_{0} ( t - τ )}}{2 j} \cdot G \cdot {e}^{j θ} \} = \frac{{M}_{0} \cdot {e}^{j {ϕ}_{0}}}{2} \cdot \{ \frac{( 1 + G \cdot {e}^{j θ} \cdot {e}^{- j {ω}_{0} τ} ) {e}^{j {ω}_{0} τ}}{2} + \frac{( 1 - G \cdot {e}^{j θ} \cdot {e}^{j {ω}_{0} τ} ) {e}^{- j {ω}_{0} τ}}{2} \} = \frac{{M}_{0} \cdot {e}^{j {ϕ}_{0}}}{4} \cdot \{ ( 1 + G \cdot {e}^{j θ} \cdot {e}^{- j {ω}_{0} τ} ) {e}^{j {ω}_{0} τ} + ( 1 - G \cdot {e}^{j θ} \cdot {e}^{j {ω}_{0} τ} ) {e}^{- j {ω}_{0} τ} \} \qquad ( 3 )$$

It is further assumed that the filter characteristic of the I-signal path is H_{I}(ω₀) and the filter characteristic of the Q-signal path is H_{Q}(ω_{O}) in the quadrature modulator 300. In this case, the baseband signal demodulated by the ideal quadrature demodulator is expressed as shown in Expression 4 below.

$$\frac{{M}_{0} \cdot {e}^{j {ϕ}_{0}}}{2} \cdot \{ I ( t ) + j \cdot Q ( t ) \cdot G \cdot {e}^{j θ} \} = \frac{{M}_{0} \cdot {e}^{j {ϕ}_{0}}}{2} \cdot \{ \frac{{H}_{I} ( {ω}_{0} ) {e}^{j {ω}_{0} t} + {H}_{I} ( - {ω}_{0} ) {e}^{- j {ω}_{0} t}}{2} + j \cdot \frac{{H}_{Q} ( {ω}_{0} ) {e}^{j {ω}_{0} ( t - τ )} - {H}_{Q} ( - {ω}_{0} ) {e}^{- j {ω}_{0} ( t - τ )}}{2 j} \cdot G \cdot {e}^{j θ} \} = \frac{{M}_{0} \cdot {e}^{j {ϕ}_{0}}}{4} \cdot \{ {H}_{I} ( {ω}_{0} ) ( 1 + \frac{{H}_{Q} ( {ω}_{0} )}{{H}_{I} ( {ω}_{0} )} G \cdot {e}^{j θ} \cdot {e}^{- j {ω}_{0} τ} ) {e}^{j {ω}_{0} t} + {H}_{I} ( - {ω}_{0} ) ( 1 - \frac{{H}_{Q} ( - {ω}_{0} )}{{H}_{I} ( - {ω}_{0} )} G \cdot {e}^{j θ} \cdot {e}^{j {ω}_{0} τ} ) {e}^{- j {ω}_{0} t} \} \qquad ( 4 )$$

In other words, Expression 4 represents the baseband signal demodulated by the ideal quadrature demodulator when the reference I signal and the reference Q signal having angular frequencies ω₀ are supplied to the quadrature modulator 300 in which the gain error between I and Q is G, the skew between I and Q is τ, the carrier phase error is θ, the filter characteristic of the I-signal path is H_{I}(ω₀) and the filter characteristic of the Q-signal path is H_{Q}(ω_{O}). Based on Expression 4, the frequency characteristic of the baseband signal included in the modulated signal s(t) output from the quadrature modulator 300 can be expressed as shown in Expression 5 below.

$$\{ \begin{matrix}A ( {ω}_{0} ) = \frac{{M}_{0} \cdot {e}^{j {ϕ}_{0}}}{4} \cdot {H}_{I} ( {ω}_{0} ) ( 1 + H ( {ω}_{0} ) G \cdot {e}^{j θ ( ω )} \cdot {e}^{- j {ω}_{0} τ} ) \\ B ( - {ω}_{0} ) = \frac{{M}_{0} \cdot {e}^{j {ϕ}_{0}}}{4} \cdot {H}_{I} ( - {ω}_{0} ) ( 1 - H ( - {ω}_{0} ) G \cdot {e}^{j θ ( ω )} \cdot {e}^{j {ω}_{0} τ} )\end{matrix} \qquad ( 5 )$$

In Expression 5, A(ω₀) represents the signal component having a positive frequency in the baseband signal, and B(−ω₀) represents the signal component having a negative frequency in the baseband signal. Furthermore, H(ω₀) represents the error in the filter characteristics between the I-signal path and the Q-signal path for the angular frequency ω₀, as shown in Expression 6 below.

$$H ( {ω}_{0} ) = \frac{{H}_{Q} ( {ω}_{0} )}{{H}_{I} ( {ω}_{0} )} \qquad ( 6 )$$

The following describes a method for calculating the frequency characteristic of the phase error, the frequency characteristic of the gain error, and the carrier phase error of the quadrature modulator 300.

The baseband signal demodulated by the quadrature demodulator from the modulated signal output by the quadrature modulator 300 supplied with only the reference I signal is expressed as shown below in Expression 7. The baseband signal demodulated by the quadrature demodulator from the modulated signal output by the quadrature modulator 300 supplied with only the reference Q signal is expressed as shown below in Expression 8.

$$\begin{matrix}\tilde{I} ( t ) = \frac{{M}_{0} \cdot {e}^{j {ϕ}_{0}}}{4} \cdot ( {H}_{I} ( ω ) {e}^{j ω t} + {H}_{I} ( - ω ) {e}^{- j ω t} ) & ( 7 ) \\ j \tilde{Q} ( t ) = \frac{{M}_{0} \cdot {e}^{j {ϕ}_{0}}}{4} \cdot ( {H}_{Q} ( ω ) {e}^{j ω ( t - τ )} - {H}_{Q} ( - ω ) {e}^{- j ω ( t - τ )} ) G \cdot {e}^{j θ {ω}_{c}} & ( 8 )\end{matrix}$$

Based on Expression 7, the I-signal frequency component corresponding to the tone signal, which is included in the modulated signal output from the quadrature modulator 300 supplied only with the reference I signal, is expressed as shown below in Expression 9. Here, A_{I}(ω) represents the signal component having a positive frequency in the I-signal frequency component, and B_{I}(−ω) represents the signal component having a negative frequency in the I-signal frequency component.

$$\{ \begin{matrix}{A}_{I} ( ω ) = \frac{{M}_{0} \cdot {e}^{j {ϕ}_{0}} {H}_{I} ( ω )}{4} \\ {B}_{I} ( - ω ) = \frac{{M}_{0} \cdot {e}^{j {ϕ}_{0}} {H}_{I} ( - ω )}{4}\end{matrix} \qquad ( 9 )$$

In the same way, based on Expression 7, the Q-signal frequency component corresponding to the tone signal, which is included in the modulated signal output from the quadrature modulator 300 supplied only with the reference Q signal, is expressed as shown below in Expression 10. Here, A_{Q}(ω) represents the signal component having a positive frequency in the Q-signal frequency component, and B_{Q}(−ω) represents the signal component having a negative frequency in the Q-signal frequency component.

$$\{ \begin{matrix}j {A}_{Q} ( ω ) = \frac{{M}_{0} \cdot {e}^{j {ϕ}_{0}}}{4} \cdot G \cdot {e}^{j θ {ω}_{c}} {H}_{Q} ( ω ) {e}^{- j ω τ} \\ j {B}_{Q} ( - ω ) = \frac{{M}_{0} \cdot {e}^{j {ϕ}_{0}}}{4} \cdot G \cdot {e}^{j θ {ω}_{c}} {H}_{Q} ( - ω ) {e}^{j ω τ}\end{matrix} \qquad ( 10 )$$

The ratio P(ω) between the positive frequency component of the I-signal frequency component and the positive frequency component of the Q-signal frequency component is expressed as shown below in Expression 11.

$$\begin{matrix}P ( ω ) = \frac{j {A}_{Q} ( ω )}{{A}_{I} ( ω )} \\ = \frac{{H}_{Q} ( ω )}{{H}_{I} ( ω )} \cdot G \cdot {e}^{j θ {ω}_{c}} {e}^{- j ω τ} \\ = \vert H ( ω ) \vert {e}^{- j ( ω τ - ∠ H ( ω ) )} \cdot G \cdot {e}^{j θ {ω}_{c}}\end{matrix} \qquad ( 11 )$$

The ratio N(−ω) between the negative frequency component of the I-signal frequency component and the negative frequency component of the Q-signal frequency component is expressed as shown below in Expression 12.

$$\begin{matrix}N ( - ω ) = \frac{j {B}_{Q} ( - ω )}{{B}_{I} ( - ω )} \\ = - \frac{{H}_{Q} ( - ω )}{{H}_{I} ( - ω )} \cdot G \cdot {e}^{j θ {ω}_{c}} {e}^{- j ω τ} \\ = - \vert H ( ω ) \vert {e}^{j ( ω τ - ∠ H ( ω ) )} \cdot G \cdot {e}^{j θ {ω}_{c}}\end{matrix} \qquad ( 12 )$$

Here, H(ω) is expressed as shown below in Expression 13.

$$H ( ω ) = \frac{{H}_{Q} ( ω )}{{H}_{I} ( ω )} \qquad ( 13 )$$

Based on Expressions 11, 12, and 13, −N(−ω)/P(ω) is expressed as shown below in Expression 14.

$$\frac{- N ( - ω )}{P ( ω )} = {e}^{2 j ( ω τ - ∠ H ( ω ) )} \qquad ( 14 )$$

Calculating half of the phase of Expression 14 leads to Expression 15 shown below.

$$\frac{1}{2} ( ∠ ( \frac{- N ( - ω )}{P ( ω )} ) ) = ω τ - ∠ H ( ω ) \qquad ( 15 )$$

From the above, the IQ error measuring section 20 can calculate the phase error of the quadrature modulator 300, based on half of the phase of −N(−ω)/P(ω).

Correcting P(ω) of Expression 11 using the phase error calculated from Expression 15 leads to Expression 16 shown below.

$${P}^{′} ( ω ) = P ( ω ) \cdot {e}^{j ( ω τ - ∠ H ( ω ) )} = \vert H ( ω ) \vert \cdot G \cdot {e}^{j {θω}_{c}} \qquad ( 16 )$$

The amplitude in Expression 16, namely the absolute value of the amplitude vector, is |H(ω)|·G. Furthermore, the phase of Expression 16 is θω_{C}.

From the above, the IQ error measuring section 20 can calculate the gain error of the quadrature modulator 300, based on the amplitude, specifically the absolute value of the amplitude vector, of P(ω) corrected according to the phase error. Furthermore, the IQ error measuring section 20 can calculate the phase error of the quadrature modulator 300 based on the phase of P(ω) corrected according to the phase error.

Based on Expressions 11, 12, and 13, −N(−ω)·P(ω) is expressed as shown below in Expression 17.

$$- N ( –ω ) \cdot P ( ω ) = {\vert H ( ω ) \vert}^{2} \cdot {G}^{2} \cdot {e}^{j 2 {θ}_{{ω}_{c}}} \qquad ( 17 )$$

The square root of the amplitude of Expression 17, namely the absolute value of the amplitude vector, is |H(ω)|·G. Furthermore, one half of the phase of Expression 17 is θω_{C}.

From the above, the IQ error measuring section 20 can calculate the gain error of the quadrature modulator 300, based on the square root of the amplitude, specifically the absolute value of the amplitude vector, of −N(−ω)·P(ω). Furthermore, the IQ error measuring section 20 can calculate the carrier phase error of the quadrature modulator 300 based on half of the phase of −N(−ω)·P(ω).

Correcting P(ω) of Expression 11 according to the carrier phase error and the gain error calculated from Expression 17 leads to Expression 18 shown below.

P′(ω)=e^{-j(ωτ-∠H(ω))} (18)

The phase of Expression 18 is ωτ−∠H(ω). From the above, the IQ error measuring section 20 can calculate the phase error of the quadrature modulator 300 based on the phase of P(ω) corrected according to the gain error and the carrier phase error.

Here, P(ω) of Expression 11 may be corrected according only to the carrier phase error calculated from Expression 17. In this case, Expression 11 is transformed into Expression 19 shown below.

P′(ω)=|H(ω)|·G·e^{j(ωτ-∠H(ω))} (19)

The phase of Expression 19 is ωτ−∠H(ω). From the above, the IQ error measuring section 20 can calculate the phase error of the quadrature modulator 300 based on the phase of P(ω) corrected according to at least the carrier phase error.

Based on Expressions 11, 12, and 13, −N(−ω)·P*(ω) is expressed as shown below in Expression 20. P*(ω) represents the complex conjugate of P(ω).

−N(−ω)·P*(ω)=|H(ω)|²·G²·e^{2j(ωτ-∠H(ω))} (20)

The square root of the amplitude of Expression 20, namely the absolute value of the amplitude vector, is |H(ω)|·G. Furthermore, one half of the phase of Expression 20 is ωτ−∠H(ω).

From the above, the IQ error measuring section 20 can calculate the gain error of the quadrature modulator 300, based on the square root of the amplitude, specifically the absolute value of the amplitude vector, of −N(−ω)·P*(ω). Furthermore, the IQ error measuring section 20 can calculate the phase error of the quadrature modulator 300 based on half of the phase of −N(−ω)·P*(ω).

Correcting P(ω) of Expression 11 according to the phase error and the gain error calculated from Expression 20 leads to Expression 21 shown below.

$${P}^{′} ( ω ) = {e}^{j {θ}_{{ω}_{c}}} \qquad ( 21 )$$

The phase of Expression 21 is θω_{C}. From the above, the IQ error measuring section 20 can calculate the carrier phase error of the quadrature modulator 300 based on the phase of P(ω) corrected according to the gain error and the phase error.

P(ω) of Expression 11 may be corrected according to only the phase error calculated from Expression 20. In this case, Expression 11 is transformed into Expression 22 shown below.

$${P}^{′} ( ω ) = \vert H ( ω ) \vert \cdot G \cdot {e}^{j {θ}_{{ω}_{c}}} \qquad ( 22 )$$

The phase of Expression 22 is θω_{C}. From the above, the IQ error measuring section 20 can calculate the carrier phase error of the quadrature modulator 300 based on the phase of P(ω) corrected according to at least the phase error.

The IQ error measuring section 20 may calculate the phase error and gain error using Expression 20 and calculate the carrier phase error using Expression 17. The IQ error measuring section 20 may calculate the gain error, the phase error, and the carrier phase error using a combination of the Expressions described above.

FIG. 16 shows exemplary frequency characteristics of the IQ error, in this case the gain error |Q/I| and the phase error ∠(Q/I), of the quadrature modulator 300.

As shown in FIG. 16, the frequency characteristic of the gain error |Q/I| is separated into gain G, which is a component that remains constant with respect to the frequency, and ripple |H(ω)|, which is a component that changes according to the frequency. Accordingly, when calculating the gain error, the IQ error measuring section 20 preferably separates the component G that is constant with respect to the frequency and the ripple |H(ω)|.

Here, the gain G component that remains constant with respect to the frequency is expressed as a coefficient that is multiplied by the entire function representing the gain error. Accordingly, the IQ error measuring section 20 can separate the constant component G and the ripple |H(ω)| by calculating the gain error for each of a plurality of angular frequencies in a multi-tone signal and estimating the function representing the gain error of the quadrature modulator 300.

As shown in FIG. 16, the frequency characteristic of the phase error ∠(Q/I) is divided into skew −ωτ, which changes linearly according to the frequency, and group delay ∠H(ω), which changes asymmetrically according to the frequency. Therefore, when calculating the phase error, the IQ error measuring section 20 preferably separates the skew τ and the group delay ∠H(ω).

The skew τ represents a first-order term in the function expressing the phase error of the quadrature modulator 300. Accordingly, the IQ error measuring section 20 can separate the skew τ and the group delay ∠H(ω) by calculating the phase error at each of a plurality of angular frequencies in a multi-tone signal and estimating the function expressing the phase error of the quadrature modulator 300.

If the equation representing H(ω) is predicted in advance, the IQ error measuring section 20 can calculate the phase error, gain error, and carrier phase error using the following method instead of the method described above.

The phase of P(ω) is expressed as shown in Expression 23 below.

<{P(ω)}=−(ωτ−<H(ω))+θ_{ω}_{_{c}} (23)

When ω=0, τ and H(ω) are both 0 as well. In other words, when ω=0, ωτ−|H(ω)|=0. Accordingly, in the case of a DC frequency component, i.e. when ω=0, the IQ error measuring section 20 can calculate the carrier phase error θω_{C} by calculating the phase of P(ω).

The IQ error measuring section 20 can use the multi-tone signal to calculate the actual measured values of P(ω) for each of the plurality of angular frequencies. Next, the IQ error measuring section 20 calculates a first-order function representing P(ω), by fitting a first-order equation with w as the variable to the actual measured value of P(ω) for each of the angular frequencies. For example, the IQ error measuring section 20 may calculate the first-order function that has the smallest error with respect to P(ω) by using the method of least squares.

The slope of the first-order function calculated in this manner represents the skew τ, and the intercept at ω=0 represents the carrier phase error. Accordingly, the IQ error measuring section 20 can calculate the skew τ as the slope of the first-order function calculated in the above manner and can calculate the carrier phase error as the intercept at ω=0.

If the equation representing H(ω) is predicted in advance, the IQ error measuring section 20 can calculate the function expressing P(ω) by fitting this predicted equation to the actual measured values of P(ω) at each of the angular frequencies. For example, the IQ error measuring section 20 may calculate the function that has the smallest error by using the method of least squares.

In the function calculated in this manner, the first-order coefficient represents the skew τ and the coefficients of other orders represent the group delay H(ω). Accordingly, the IQ error measuring section 20 can calculate the skew τ as the coefficient of the first-order term in the function calculated in this way and calculate the group delay H(ω) as the coefficients of the terms other than the first-order term.

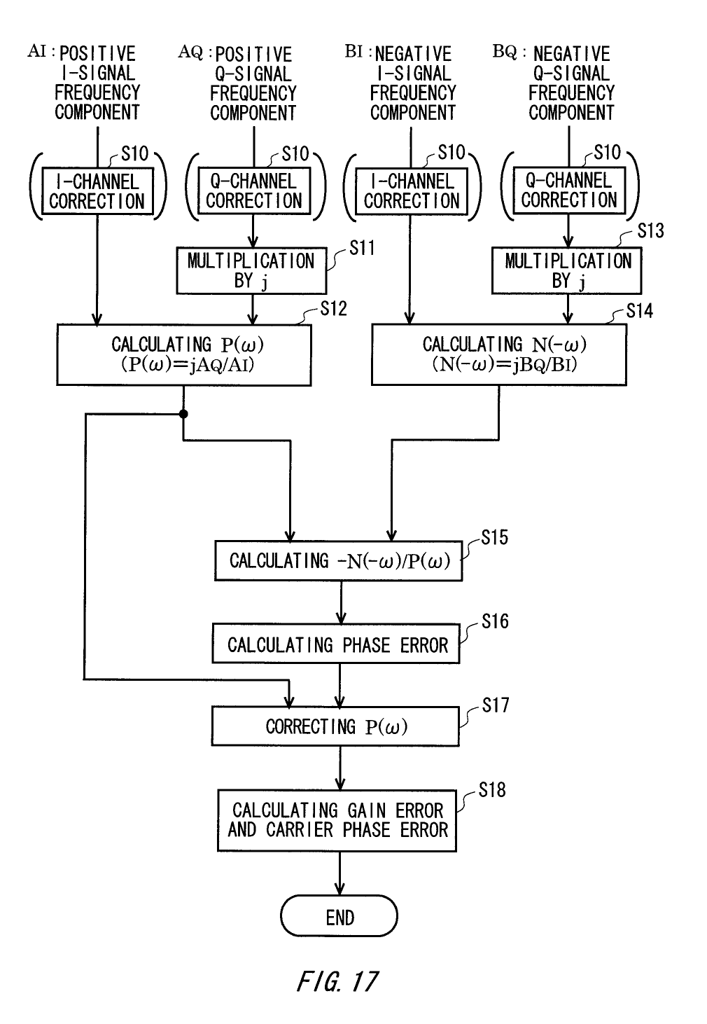

FIG. 17 shows an exemplary process flow of the calculating section 122 according to the present embodiment. The calculating section 122 performs the process shown in FIG. 17 when calculating the phase error, gain error, and carrier phase error of the quadrature modulator 300, for example.

Prior to this process, the calculating section 122 receives from the extracting section 120 a positive frequency component A_{I} in the I-signal frequency component, a positive frequency component A_{Q} in the Q-signal frequency component, a negative frequency component B_{I} in the I-signal frequency component, and a negative frequency component B_{Q} in the Q-signal frequency component.

Next, the calculating section 122 performs channel correction on the input signal components (S10). Specifically, the calculating section 122 uses the correction coefficient for correcting the channel of the I-signal path to perform channel correction on the positive frequency component (A_{I}) in the I-signal frequency component and the negative frequency component (B_{I}) in the I-signal frequency component. Furthermore, the calculating section 122 uses the correction coefficient for correcting the channel of the Q-signal path to perform channel correction on the positive frequency component (A_{Q}) in the Q-signal frequency component and the negative frequency component (B_{Q}) in the Q-signal frequency component.

Next, the calculating section 122 multiplies the positive frequency component A_{Q} in the Q-signal frequency component by an imaginary unit j (S11). The calculating section 122 calculates P(ω)=(jA_{Q}/A_{I}) by dividing j×A_{Q}, which is the product of the imaginary unit j and the positive frequency component A_{Q} in the Q-signal frequency component, by the positive frequency component A_{I} in the I-signal frequency component (S12).

The calculating section 122 multiplies the negative frequency component B_{Q} in the Q-signal frequency component by an imaginary unit j (S13). The calculating section 122 calculates N(−ω)=(jB_{Q}/B_{I}) by dividing j×B_{Q}, which is the product of the imaginary unit j and the negative frequency component B_{Q} in the Q-signal frequency component, by the negative frequency component B_{I} in the I-signal frequency component (S14).

Next, the calculating section 122 calculates −N(−ω)/P(ω) by dividing N(−ω) by P(ω) and inverting the sign of the result (S 15). The calculating section 122 then calculates the phase error for each of one or more angular frequencies ω at which a tone signal occurs (S16). Specifically, the calculating section 122 calculates the phase error to be half of the phase of −N(−ω)/P(ω).

Next, the calculating section 122 corrects P(ω) by multiplying the phase error calculated at step S16 by P(ω) calculated at step S12 (S17). As a result, the calculating section 122 can eliminate the effect of the phase error of the quadrature modulator 300 from P(ω).

Next, the calculating section 122 calculates the gain error and the carrier phase error for each of one or more angular frequencies w at which a tone signal occurs, based on the corrected P(ω) (S18). Specifically, the calculating section 122 calculates the gain error to be the amplitude of the corrected P(ω). The calculating section 122 calculates the carrier frequency error to be the phase of the corrected P(ω).

The calculating section 122 described above can accurately and easily measure the phase error, gain error, and carrier phase error of the quadrature modulator 300. Furthermore, the calculating section 122 can calculate the frequency characteristics of the gain error and the phase error by performing the above process for the angular frequency ωₖ of each tone signal in a multi-tone signal.

The calculating section 122 may separate the frequency characteristic of the gain error into a component that is constant with respect to the frequency and a ripple that changes according to the frequency. The calculating section 122 may separate the frequency characteristic of the phase error into a skew that is expressed as a first-order term of the frequency and a group delay that is expressed as the terms other than the first-order term of the frequency. As a result, the calculating section 122 can calculate the characteristics of the IQ error of the extracting section 120 in more detail.

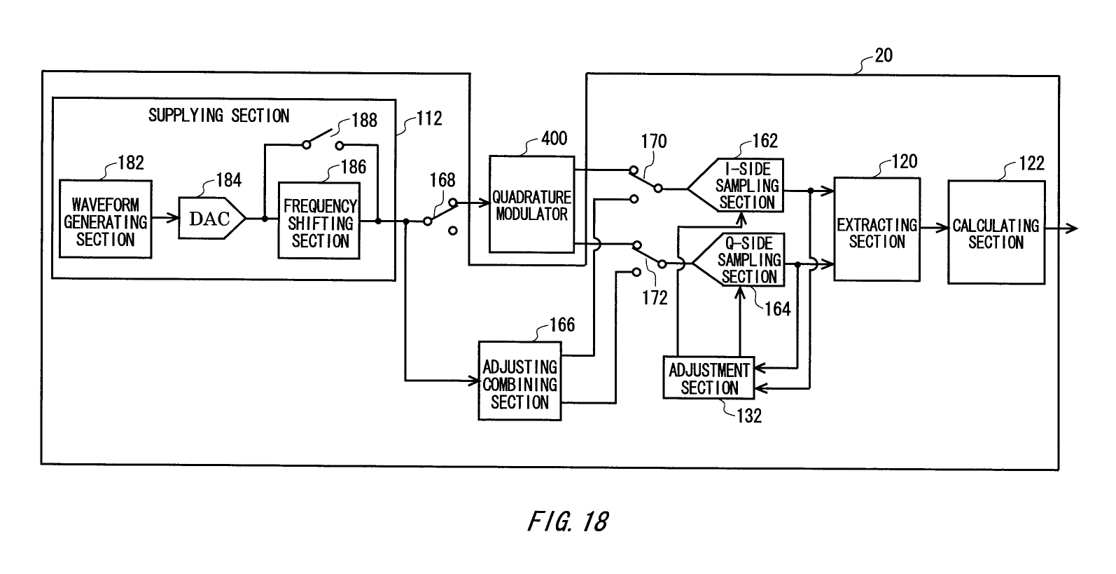

FIG. 18 shows an exemplary configuration of the IQ error measuring section 20 according to a modification of the present embodiment, along with a quadrature demodulator 400. The IQ error measuring section 20 of the present modification has substantially the same function and configuration as the IQ error measuring section 20 shown in FIG. 12, and therefore components having substantially the same function are given the same reference numerals and further description is omitted.

The IQ error measuring section 20 of the present modification measures the carrier phase error, the frequency characteristic of the gain error, and the frequency characteristic of the phase error between I and Q in the quadrature demodulator 400, instead of in the quadrature modulator 300. The IQ error measuring section 20 of the present modification includes the supplying section 112, an I-side sampling section 162, a Q-side sampling section 164, the extracting section 120, the calculating section 122, an adjustment dividing section 166, an output switching section 168, an I-side input switching section 170, a Q-side input switching section 172, and an adjusting section 132.

The supplying section 112 shifts a first modulated signal corresponding to a signal obtained by orthogonally modulating the I component in an IQ signal causing a tone signal and/or a second modulated signal corresponding to a signal obtained by orthogonally modulating a Q component of the IQ signal to have a time difference therebetween, and supplies the resulting signals to the quadrature demodulator 400. In other words, the supplying section 112 outputs, as the first modulated signal, the modulated signal output as a result of an ideal quadrature modulator orthogonally modulating the reference I signal output from the supplying section 112 described in FIG. 12. Furthermore, the supplying section 112 outputs, as the second modulated signal, the modulated signal output as a result of an ideal quadrature modulator orthogonally modulating the reference Q signal output from the supplying section 112 described in FIG. 12.

The supplying section 112 may shift the first modulated signal, which corresponds to a signal obtained by orthogonally modulating the I component of an IQ signal causing a multi-tone signal with either a positive frequency or a negative frequency, and the second modulated signal, which corresponds to a signal obtained by orthogonally modulating the Q component in this IQ signal, to have a time difference therebetween, and supply the resulting signals to the quadrature demodulator 400. Instead, the supplying section 112 may shift the first modulated signal, which corresponds to a signal obtained by orthogonally modulating the I component of an IQ signal causing a multi-tone signal in which the aliasing components do not overlap, and the second modulated signal, which corresponds to a signal obtained by orthogonally modulating the Q component in this IQ signal, to have a time difference therebetween, and supply the resulting signals to the quadrature demodulator 400.

The supplying section 112 may include a waveform generating section 182, a DAC 184, a frequency shifting section 186, and a bypass switch 188. The waveform generating section 182 shifts the waveform data of the first modulated signal and/or the waveform data of the second modulated signal to have a time difference therebetween. The DAC 184 performs DA conversion on the waveform data supplied from the waveform generating section 182, and outputs the resulting first modulated signal and second modulated signal.

The frequency shifting section 186 up-converts the carrier frequencies of the first modulated signal and the second modulated signal output from the supplying section 112, and supplies the resulting signals to the quadrature demodulator 400. If the up-conversion by the frequency shifting section 186 is unnecessary, the bypass switch 188 may cause the first modulated signal and the second modulated signal output by the DAC 184 to bypass the frequency shifting section 186 and be supplied to the quadrature demodulator 400.

As described above, the supplying section 112 can shift the first modulated signal and/or the second modulated signal to have a time difference therebetween, and supply the resulting signals to the quadrature demodulator 400. The quadrature demodulator 400 can output a baseband signal obtained by orthogonally demodulating the first modulated signal. The extracting section 120 can output a baseband signal obtained by orthogonally demodulating the second modulated signal.

The I-side sampling section 162 samples and digitizes the signal corresponding to the I component in the baseband signal output from the quadrature demodulator 400. The Q-side sampling section 164 samples and digitizes the signal corresponding to the Q component in the baseband signal output from the quadrature demodulator 400.

The extracting section 120 extracts the frequency component corresponding to the tone signal included in the baseband signal obtained by the quadrature demodulator 400 demodulating the first modulated signal. The extracting section 120 also extracts the frequency component corresponding to the tone signal included in the baseband signal obtained by the quadrature demodulator 400 demodulating the second modulated signal.

The calculating section 122 calculates the carrier phase error, the frequency characteristic of the gain error, and the frequency characteristic of the phase error of the quadrature demodulator 400 based on the frequency component corresponding to the tone signal in the baseband signal resulting from the demodulation of the first modulated signal and the frequency component corresponding to the tone signal in the baseband signal resulting from the demodulation of the second modulated signal. The calculating section 122 may also calculate the carrier phase error of the quadrature demodulator 400.

Here, the calculating section 122 treats the frequency component corresponding to the tone signal in the baseband signal resulting from the demodulation of the first modulated signal as the Q-signal frequency component. Furthermore, the calculating section 122 treats the frequency component corresponding to the tone signal in the baseband signal resulting from the demodulation of the second modulated signal as the Q-signal frequency component. The calculating section 122 calculates the phase error, gain error, and carrier phase error in the same manner as the calculating section 122 described in relation to FIG. 12.

As a result, the IQ error measuring section 20 of the present modification can easily and accurately calculate the phase error, gain error, and carrier phase error of the quadrature demodulator 400.

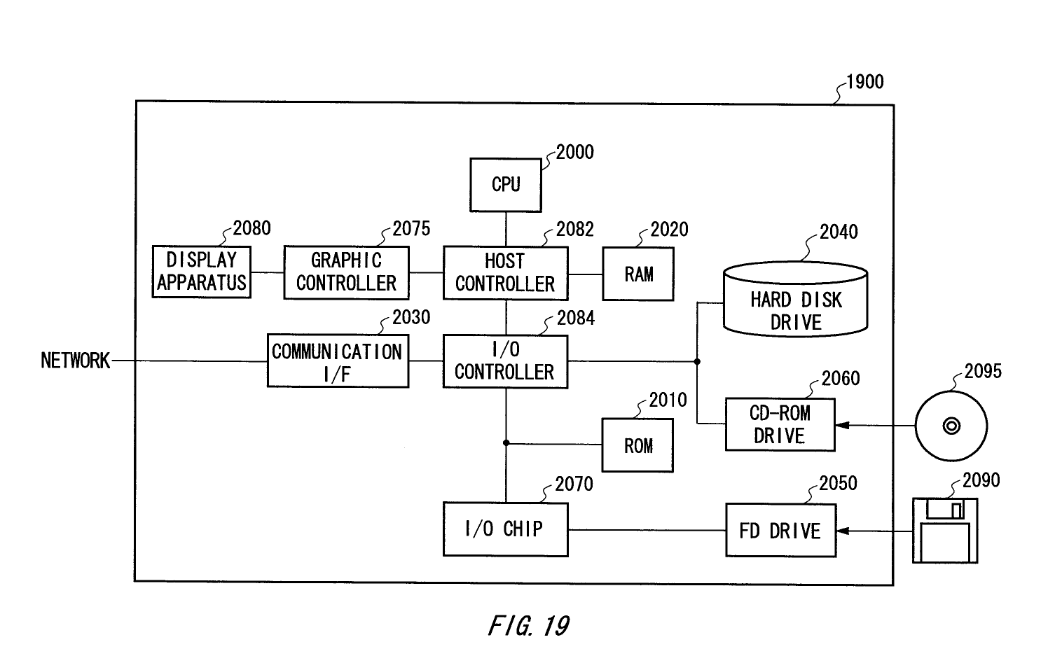

FIG. 19 shows an example of a hardware configuration of a computer 1900 according to the present embodiment. The computer 1900 according to the present embodiment is provided with a CPU peripheral including a CPU 2000, a RAM 2020, a graphic controller 2075, and a display apparatus 2080, all of which are connected to each other by a host controller 2082; an input/output section including a communication interface 2030, a hard disk drive 2040, and a CD-ROM drive 2060, all of which are connected to the host controller 2082 by an input/output controller 2084; and a legacy input/output section including a ROM 2010, a flexible disk drive 2050, and an input/output chip 2070, all of which are connected to the input/output controller 2084.

The host controller 2082 is connected to the RAM 2020 and is also connected to the CPU 2000 and graphic controller 2075 accessing the RAM 2020 at a high transfer rate. The CPU 2000 operates to control each section based on programs stored in the ROM 2010 and the RAM 2020. The graphic controller 2075 acquires image data generated by the CPU 2000 or the like on a frame buffer disposed inside the RAM 2020 and displays the image data in the display apparatus 2080. In addition, the graphic controller 2075 may internally include the frame buffer storing the image data generated by the CPU 2000 or the like.

The input/output controller 2084 connects the communication interface 2030 serving as a relatively high speed input/output apparatus, and the hard disk drive 2040, and the CD-ROM drive 2060 to the host controller 2082. The communication interface 2030 communicates with other apparatuses via a network. The hard disk drive 2040 stores the programs and data used by the CPU 2000 housed in the computer 1900. The CD-ROM drive 2060 reads the programs and data from a CD-ROM 2095 and provides the read information to the hard disk drive 2040 via the RAM 2020.

Furthermore, the input/output controller 2084 is connected to the ROM 2010, and is also connected to the flexible disk drive 2050 and the input/output chip 2070 serving as a relatively high speed input/output apparatus. The ROM 2010 stores a boot program performed when the computer 1900 starts up, a program relying on the hardware of the computer 1900, and the like. The flexible disk drive 2050 reads programs or data from a flexible disk 2090 and supplies the read information to the hard disk drive 2040 via the RAM 2020. The input/output chip 2070 connects the flexible disk drive 2050 to the input/output controller 2084 along with each of the input/output apparatuses via, a parallel port, a serial port, a keyboard port, a mouse port, or the like.

The programs provided to the hard disk drive 2040 via the RAM 2020 are stored in a storage medium, such as the flexible disk 2090, the CD-ROM 2095, or an IC card, and provided by a user. The programs are read from storage medium, installed in the hard disk drive 2040 inside the computer 1900 via the RAM 2020, and performed by the CPU 2000.

The programs that are installed in the computer 1900 and cause the computer 1900 function as the error amount calculating section 30 that calculates the EVM of an OFDM signal include an ideal signal calculating module, a prediction signal calculating module, and an EVM calculating module. The programs that are installed in the computer 1900 and cause the computer 1900 function as the error amount calculating section 30 that calculates the EVM of an SC-FDMA signal include an ideal signal calculating module, a prediction signal calculating module, an EVM calculating module, and a time response conversion module. These programs and modules prompt the CPU 2000 or the like to make the computer 1900 function as the ideal signal calculating section 32, the prediction signal calculating section 34, the EVM calculating section 36, and the time response converting section 38.

The information processes recorded in these programs are read by the computer 1900 to cause the computer 1900 to function as software and hardware described above, which are exemplified by the specific means of the ideal signal calculating section 32, the prediction signal calculating section 34, the EVM calculating section 36, and the time response converting section 38. With these specific means, a unique error amount calculating section 30 suitable for an intended use can be configured by realizing the calculations or computations appropriate for the intended use of the computer 1900 of the present embodiment.

For example, if there is communication between the computer 1900 and an external apparatus or the like, the CPU 2000 performs the communication program loaded in the RAM 2020, and provides the communication interface 2030 with communication processing instructions based on the content of the process recorded in the communication program. The communication interface 2030 is controlled by the CPU 2000 to read the transmission data stored in the transmission buffer area or the like on the storage apparatus, such as the RAM 2020, the hard disk drive 2040, the flexible disk 2090, or the CD-ROM 2095, and send this transmission data to the network, and to write data received from the network onto a reception buffer area on the storage apparatus. In this way, the communication interface 2030 may transmit data to and from the storage apparatus through DMA (Direct Memory Access). As another possibility, the CPU 2000 may transmit the data by reading the data from the storage apparatus or communication interface 2030 that are the origins of the transmitted data, and writing the data onto the communication interface 2030 or the storage apparatus that are the transmission destinations.

The CPU 2000 may perform various processes on the data in the RAM 2020 by reading into the RAM 2020, through DMA transmission or the like, all or a necessary portion of the database or files stored in the external apparatus such as the hard disk drive 2040, the CD-ROM drive 2060, the CD-ROM 2095, the flexible disk drive 2050, or the flexible disk 2090. The CPU 2000 writes the processed data back to the external apparatus through DMA transmission or the like. In this process, the RAM 2020 is considered to be a section that temporarily stores the content of the external storage apparatus, and therefore the RAM 2020, the external apparatus, and the like in the present embodiment are referred to as a memory, a storage section, and a storage apparatus. The variety of information in the present embodiment, such as the variety of programs, data, tables, databases, and the like are stored on the storage apparatus to become the target of the information processing. The CPU 2000 can hold a portion of the RAM 2020 in a cache memory and read from or write to the cache memory. With such a configuration as well, the cache memory serves part of the function of the RAM 2020, and therefore the cache memory is also included with the RAM 2020, the memory, and/or the storage apparatus in the present invention, except when a distinction is made.

The CPU 2000 executes the various processes such as the computation, information processing, condition judgment, searching for/replacing information, and the like included in the present embodiment for the data read from the RAM 2020, as designated by the command sequence of the program, and writes the result back onto the RAM 2020. For example, when performing condition judgment, the CPU 2000 judges whether a variable of any type shown in the present embodiment fulfills a condition of being greater than, less than, no greater than, no less than, or equal to another variable or constant. If the condition is fulfilled, or unfulfilled, depending on the circumstances, the CPU 2000 branches into a different command sequence or acquires a subroutine.

The CPU 2000 can search for information stored in a file in the storage apparatus, the database, and the like. For example, if a plurality of entries associated respectively with a first type of value and a second type of value are stored in the storage apparatus, the CPU 2000 can search for entries fulfilling a condition designated by the first type of value from among the plurality of entries stored in the storage apparatus. The CPU 2000 can then obtain the second type of value associated with the first type of value fulfilling the prescribed condition by reading the second type of value stored at the same entry.

The programs and modules shown above may also be stored in an external storage medium. The flexible disk 2090, the CD-ROM 2095, an optical storage medium such as a DVD or CD, a magneto-optical storage medium, a tape medium, a semiconductor memory such as an IC card, or the like can be used as the storage medium. Furthermore, a storage apparatus such as a hard disk or RAM that is provided with a server system connected to the Internet or a specialized communication network may be used to provide the programs to the computer 1900 via the network.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A measurement apparatus that measures a characteristic of a device under measurement, which includes a quadrature modulator or a quadrature demodulator, the measurement apparatus comprising:
an IQ error measuring section that measures a frequency characteristic of an IQ error of the device under measurement; and
an error amount calculating section that calculates EVM based on a constellation error, at each of a plurality of frequencies, between an ideal signal to be output in response to input of a predetermined signal into a model of the device under measurement that does not include an IQ error and a prediction signal that is to be output in response to the input of the predetermined signal into a model of the device under measurement that includes the IQ error measured by the IQ error measuring section, wherein
the error amount calculating section corrects a signal component at each of the frequencies in the prediction signal according to a channel characteristic, and calculates the constellation error.

2. The measurement apparatus according to claim 1, wherein
the error amount calculating section multiplies the signal component at each of the frequencies in the prediction signal by a correction coefficient representing the channel characteristic based on the IQ error.

3. The measurement apparatus according to claim 2, wherein
the error amount calculating section calculates the correction coefficient based on a signal component of a reference signal at a given frequency, a signal component applied to the given frequency by a reference signal of a mirror frequency of the given frequency, and the IQ error.

4. The measurement apparatus according to claim 2, wherein
when a difference between a filter characteristic of an I-signal path and a filter characteristic of a Q-signal path is less than a predetermined value, the error amount calculating section calculates the correction coefficient based on a component of the corresponding frequency of the filter characteristic of the I-signal path and the IQ error.

5. The measurement apparatus according to claim 1, wherein
the error amount calculating section calculates, as the EVM, a root mean square of a constellation error between the ideal signal and the prediction signal at each of a plurality of frequencies.

6. The measurement apparatus according to claim 5, further comprising a noise measuring section that measures a signal-to-noise ratio of the device under measurement, wherein
the error amount calculating section outputs, as the EVM, a square root of a sum of a square of the signal-to-noise ratio and a square of the constellation error.

7. A program that causes a computer to function as the error amount calculating section in the measurement apparatus according to claim 1.

8. A method of measuring a characteristic of a device under measurement, which includes a quadrature modulator or a quadrature demodulator, the method comprising:
measuring a frequency characteristic of an IQ error of the device under measurement; and
calculating EVM based on a constellation error, at each of a plurality of frequencies, between an ideal signal to be output in response to input of a predetermined signal into a model of the device under measurement that does not include an IQ error and a prediction signal that is to be output in response to the input of the predetermined signal into a model of the device under measurement that includes the IQ error measured by the IQ error measuring section, wherein
calculating the EVM includes correcting a signal component at each of the frequencies in the prediction signal according to a channel characteristic, and then calculating the constellation error.
